(19) United States
(12) Patent Application Publication
(10) Pub. No.: US 2026/0242932 A1
(43) Pub. Date: Aug. 20, 2026

(54) METHOD FOR SELECTIVELY MODIFYING SUBSTRATE SURFACE, METHOD FOR PRODUCING SURFACE-TREATED SUBSTRATE, AND COMPOSITION

(71) Applicant: JSR CORPORATION, Tokyo (JP)

(72) Inventors: Hiroyuki Komatsu, Tokyo (JP); Shin-Ichirou Hagi, Tokyo (JP); Ryou Suhara, Tokyo (JP)

(73) Assignee: JSR CORPORATION, Tokyo (JP)

(21) Appl. No.: 19/160,460

(22) PCT Filed: Feb. 26, 2024
(86) PCT No.: PCT/JP2024/006855

§ 371 Date: Aug. 27, 2025

(30) Foreign Application Priority Data
Feb. 28, 2023 (JP) 2023-029874

(51) Int. Cl. C23C 16/04; B05D 1/00; B05D 3/02; B05D 3/10

(52) U.S. Cl. CPC C23C 16/042; B05D 1/005; B05D 3/0254; B05D 3/107; B05D 2202/00; B05D 2401/21

(57) ABSTRACT

The present invention provides a method for selectively modifying a substrate surface, the method comprising a step for applying a composition to the surface of the substrate, the composition containing water and a compound (A) having a nitrogen-containing heterocyclic ring and a monovalent organic group having 4 or more carbon atoms.

### CROSS-REFERENCE TO RELATED APPLICATION

This application claims priority based on Japanese Patent Application No. 2023-029874 filed on Feb. 28, 2023, the entirety of which is incorporated herein by reference.

The disclosure relates to a method for selectively modifying a substrate surface, a method for producing a surface-treated substrate, and a composition.

### TECHNICAL FIELD

### Background Technology

In semiconductor manufacturing processes, in order to cover and protect a partial region on a substrate surface, an organic film may be formed in the partial region, and various treatments such as formation and etching of metal layer may be performed on the substrate after organic film formation. When forming the organic film on the substrate surface to protect the partial region of the substrate surface, it is required to be capable of forming a film with high selectivity for the region to be protected on the substrate surface, along with further miniaturization of semiconductor devices (for example, see Patent Document 1).

Patent Document 1 discloses that a composition containing a solvent and a first polymer, which has a group including a first functional group that bonds with metal included in a first region at a terminal of a main chain or side chain, is coated on a surface of a substrate having a first region including metal on a surface layer, and the coating film formed by coating the composition is heated to selectively surface-modify the first region with the first polymer. Patent Document 1 also discloses using solvents capable of dissolving or dispersing the first polymer, such as alcohol-based solvents, ether-based solvents, ketone-based solvents, amide-based solvents, and hydrocarbon-based solvents, as solvents used for preparing the composition.

### RELATED ART DOCUMENTS

### Patent Documents

Patent Document 1: International Publication No. WO 2018/043304

### SUMMARY OF INVENTION

### Problems to be Solved by the Invention

If water can be used as the main component of the solvent in a composition used for selective modification of a substrate surface, it is expected that environmental burden can be reduced and the handleability of the composition can be improved. However, in a composition including water, precipitation of components included in the composition tends to occur easily, and the storage stability of the composition tends to decrease. Particularly, in the case of imparting water repellency to the substrate surface by selectively modifying the substrate surface, a material with high hydrophobicity is used as the film forming material. Therefore, there is concern that the storage stability of the composition is more likely to decrease due to insufficient solubility of the film forming material in water.

Moreover, from the viewpoint of stabilizing product quality in semiconductor manufacturing processes and from the viewpoint of suppressing a decrease in product yield, when protecting a partial region on a substrate surface, it is required to selectively protect the region to be protected. Furthermore, it is required to modify the region to be protected with high density, thereby making it difficult for impurities to adhere to the protected region (that is, achieving high blocking performance).

The disclosure has been made in view of the above problems, and the main object is to provide a method for selectively modifying a substrate surface and a composition that achieve high storage stability of the composition used for selective modification of substrate surface, and moreover can modify the substrate surface with high selectivity and high density.

### Means for Solving the Problems

In order to solve the above problems, the disclosure provides the following means.

[1] A method for selectively modifying a substrate surface, including: a step of coating a composition on a surface of a substrate, in which the composition includes a compound (A), which has a nitrogen-containing heterocyclic ring and a monovalent organic group having 4 or more carbon atoms, and water.

[2] A method for producing a surface-treated substrate, including: a step of coating a composition on a surface of a substrate to selectively modify the surface of the substrate, in which the composition includes a compound (A), which has a nitrogen-containing heterocyclic ring and a monovalent organic group having 4 or more carbon atoms, and water.

[3] A composition, used for selectively modifying a substrate surface, the composition including: a compound (A), which has a nitrogen-containing heterocyclic ring and a monovalent organic group having 4 or more carbon atoms, and water.

### Effects of the Invention

According to the disclosure, the storage stability of the composition used for selective modification of substrate surface is high, and moreover the substrate surface can be modified with high selectivity and high density.

### DESCRIPTION OF THE EMBODIMENTS

Hereinafter, matters related to the embodiments will be described in detail. In this specification, numerical ranges described using “~ (to)” mean that the numerical values described before and after “~ (to)” are included as lower limit values and upper limit values. Unless otherwise specified, each component may be used alone or in combination of two or more.

### «Method for Selectively Modifying Substrate Surface and Composition»

The method for selectively modifying a substrate surface of the disclosure (hereinafter also simply referred to as “selective modification method”) includes a step of coating a composition (hereinafter also referred to as “surface modification composition”) on a surface of a substrate. The surface modification composition is an aqueous liquid composition and contains compound (A) having a nitrogen-containing heterocyclic ring and a monovalent organic group having 4 or more carbon atoms, and water, as a solvent component. Hereinafter, the surface modification composition will be described first, followed by description of the method for selectively modifying a substrate surface using the surface modification composition.

### <Surface Modification Composition>

The surface modification composition is used as a surface treatment liquid for forming a film on a substrate surface to perform surface modification of the substrate. Water repellency is imparted to the region where a film is formed by the surface modification composition. The film formed by the surface modification composition is typically a self-assembled monolayer (SAM) formed by adsorption of compound (A) on the substrate surface. Each component included in the surface modification composition and components optionally blended as required (hereinafter also referred to as “other components”) will be described hereinafter.

### Compound (A)

Compound (A) has a nitrogen-containing heterocyclic ring and a monovalent organic group having 4 or more carbon atoms (hereinafter also referred to as “monovalent organic group R¹”). By using compound (A) as a monolayer forming material, adsorption ability to a substrate (particularly metal regions) is exhibited by the nitrogen-containing heterocyclic ring portion, and water repellency is exhibited by the monovalent organic group R¹ portion. Thereby, excellent water repellency can be imparted to the substrate surface. In particular, by having a nitrogen-containing heterocyclic ring, compound (A) can enhance the water solubility of compound (A) while highly selectively and densely modifying metal regions through interaction with metal. The “interaction” referred to here is, for example, a chemical bond, including covalent bonds, ionic bonds, coordinate bonds, and the like. In the case of a nitrogen atom in the nitrogen-containing heterocyclic ring forming a coordinate bond with metal, it is possible to enhance the bonding force between the metal atom and the nitrogen-containing heterocyclic ring.

Compound (A) is a compound (low molecular weight compound) different from a polymer. The molecular weight of compound (A) is preferably 1,000 or less, more preferably 800 or less, further preferably 700 or less, and even more preferably 600 or less from the viewpoint of ensuring solubility in water. Also, from the viewpoint of obtaining a film with good heat resistance, the molecular weight of compound (A) is preferably 120 or more, more preferably 150 or more, and further preferably 200 or more.

The nitrogen-containing heterocyclic ring included in compound (A) may be an aromatic heterocyclic ring or a non-aromatic heterocyclic ring. In addition, the nitrogen-containing heterocyclic ring included in compound (A) may be a monocyclic ring or a condensed ring. Specific examples of nitrogen-containing aromatic heterocyclic ring include pyrrole ring, imidazole ring, pyrazole ring, triazole ring, tetrazole ring, pyridine ring, pyrimidine ring, pyridazine ring, quinoline ring, isoquinoline ring, benzimidazole ring, benzotriazole ring, substituted benzotriazole ring, carbazole ring, acridine ring, pyrazine ring, etc. Examples of substituted benzotriazole ring include rings having substituents such as alkyl groups having 1 to 3 carbon atoms, halogen atoms (fluorine atom, chlorine atom, bromine atom, iodine atom, etc.), and nitro groups at the 5-position or 6-position.

Specific examples of nitrogen-containing non-aromatic heterocyclic ring include piperidine ring, piperazine ring, hexamethyleneimine ring, diazabicycloundecene, diazabicyclo[4.3.0]non-5-ene, 1,5,7-triazabicyclo[4.4.0]dec-5-ene, etc. The nitrogen-containing heterocyclic ring included in compound (A) preferably has only nitrogen atoms as heteroatoms in the ring skeleton.

Among the above, the nitrogen-containing heterocyclic ring included in compound (A) is preferably at least one selected from the group consisting of imidazole ring, pyrazole ring, triazole ring, pyridine ring, benzimidazole ring, benzotriazole ring, substituted benzotriazole ring, piperidine ring, piperazine ring, hexamethyleneimine ring, diazabicycloundecene, and 1,5,7-triazabicyclo[4.4.0]dec-5-ene, and more preferably at least one selected from the group consisting of imidazole ring, pyridine ring, benzimidazole ring, benzotriazole ring, substituted benzotriazole ring, piperidine ring, piperazine ring, and 1,5,7-triazabicyclo[4.4.0]dec-5-ene.

Compound (A) may include the nitrogen-containing heterocyclic ring in a salt form (that is, at least one nitrogen atom included in the ring skeleton of the nitrogen-containing heterocyclic ring is in a cationic form). In the case of the nitrogen-containing heterocyclic ring being in a salt form, the counter ion may be any anionic counter ion and is not particularly limited. Specific examples of counter ion include, for example, chloride ion, bromide ion, iodide ion, triazole anion, benzotriazole anion, 5-methylbenzotriazole anion, etc.

The monovalent organic group R¹ included in compound (A) is preferably a monovalent hydrocarbon group having 4 or more carbon atoms, a monovalent halogenated hydrocarbon group having 4 or more carbon atoms, —R³—O—R⁶, or —CR⁴(OH)—R⁶ (where R³ is an alkanediyl group having 1 to 3 carbon atoms, R⁴ is a hydrogen atom or a methyl group, and R⁶ is a monovalent hydrocarbon group having 4 or more carbon atoms; the same applies hereinafter) from the viewpoint of obtaining a film excellent in water repellency by coating the surface modification composition on the substrate surface. The number of carbon atoms in the monovalent organic group R¹ is, for example, 4 to 40 carbon atoms.

Here, in this specification, “hydrocarbon group” means to include a chain hydrocarbon group, an alicyclic hydrocarbon group, and an aromatic hydrocarbon group. “Chain hydrocarbon group” means a linear hydrocarbon group and a branched hydrocarbon group that do not include a cyclic structure and are composed only of a chain structure. The chain hydrocarbon group may be saturated or unsaturated. “Alicyclic hydrocarbon group” means a hydrocarbon group that includes only an alicyclic hydrocarbon structure as a ring structure and does not include an aromatic ring structure. The alicyclic hydrocarbon group does not need to be composed only of an alicyclic hydrocarbon structure, and also includes groups having a chain structure in part thereof. “Aromatic hydrocarbon group” means a hydrocarbon group that includes an aromatic ring structure as a ring structure. However, the aromatic hydrocarbon group does not need to be composed only of an aromatic ring structure, and may include a chain structure or an alicyclic hydrocarbon structure in part thereof.

As specific examples of the monovalent organic group R¹, examples of monovalent hydrocarbon group having 4 or more carbon atoms include a monovalent chain hydrocarbon group having 4 to 40 carbon atoms, a monovalent alicyclic hydrocarbon group having 4 to 40 carbon atoms, and a monovalent aromatic hydrocarbon group having 6 to 40 carbon atoms. As specific examples thereof, examples of monovalent chain hydrocarbon group having 4 to 40 carbon atoms include alkyl groups such as n-butyl group, isobutyl group, sec-butyl group, tert-butyl group, n-pentyl group, isopentyl group, n-hexyl group, n-octyl group, n-nonyl group, n-decyl group, n-undecyl group, n-dodecyl group, n-tridecyl group, n-tetradecyl group, n-pentadecyl group, n-hexadecyl group, eicosyl group, and docosyl group; alkenyl groups such as propenyl group, butenyl group, hexenyl group, octenyl group, decenyl group, and dodecenyl group; alkynyl groups such as propynyl group and butynyl group; etc.

Examples of monovalent alicyclic hydrocarbon group having 4 to 40 carbon atoms include monocyclic alicyclic saturated hydrocarbon groups such as cyclopentyl group, cyclohexyl group, methylcyclopentyl group, ethylcyclopentyl group, methylcyclohexyl group, and ethylcyclohexyl group; monocyclic alicyclic unsaturated hydrocarbon groups such as cyclopentenyl group, cyclohexenyl group, methylcyclopentenyl group, and methylcyclohexenyl group; polycyclic alicyclic saturated hydrocarbon groups such as norbornyl group, adamantyl group, and tricyclodecyl group; polycyclic alicyclic unsaturated hydrocarbon groups such as norbornenyl group and tricyclodecenyl group; etc.

Examples of monovalent aromatic hydrocarbon group having 6 to 40 carbon atoms include aryl groups such as phenyl group, tolyl group, xylyl group, naphthyl group, and anthryl group; aralkyl groups such as benzyl group, phenethyl group, naphthylmethyl group, and anthrylmethyl group; etc.

Examples of monovalent halogenated hydrocarbon group having 4 or more carbon atoms include groups in which any hydrogen atom of the groups exemplified as the monovalent hydrocarbon group is substituted with a halogen atom (fluorine atom, chlorine atom, bromine atom, iodine atom, etc.).

In the group represented by —R³—O—R⁶ or —CR⁴(OH)—R⁶, examples of the monovalent hydrocarbon group represented by R⁶ include the same groups as the groups shown as specific examples in the case where the monovalent organic group R¹ is a monovalent hydrocarbon group having 4 or more carbon atoms.

In terms of the point of being able to impart excellent water repellency to the substrate surface, among the above, the monovalent organic group R¹ is preferably a monovalent hydrocarbon group having 4 or more carbon atoms, —R³—O—R⁶, or —CR⁴(OH)—R⁶, more preferably a monovalent chain hydrocarbon group having 4 or more carbon atoms, —R³—O—R⁷, or —CR⁴(OH)—R⁷ (where R⁷ is a monovalent chain hydrocarbon group having 4 or more carbon atoms), even more preferably a linear or branched alkyl group having 4 or more carbon atoms, —R³—O—R⁸, or —CR⁴(OH)—R⁸ (where R⁸ is a linear or branched alkyl group having 4 or more carbon atoms), and still more preferably a linear alkyl group having 4 or more carbon atoms, —R³—O—R⁹, or —CR⁴(OH)—R⁹ (where R⁹ is a linear alkyl group having 4 or more carbon atoms).

The number of carbon atoms in the monovalent organic group R¹ is preferably 5 or more, more preferably 8 or more, and even more preferably 9 or more from the viewpoint of imparting excellent water repellency to the substrate surface. Also, the number of carbon atoms in the monovalent organic group R¹ is preferably 30 or less, more preferably 20 or less, even more preferably 18 or less, and still more preferably 15 or less from the viewpoint of improving the solubility of compound (A) in water and from the viewpoint of suppressing a decrease in adsorption ability of compound (A) to the substrate.

Compound (A) may further have a monovalent organic group having 1 to 3 carbon atoms as long as compound (A) has one or more monovalent organic groups R¹ having 4 or more carbon atoms in one molecule. Specific examples of such groups include alkyl groups having 1 to 3 carbon atoms (methyl group, ethyl group, propyl group), acetyl group, formyl group, etc.

Compound (A) may have one or more nitrogen-containing heterocyclic rings and one or more monovalent organic groups R¹, respectively, and the structure thereof is not particularly limited. The number of nitrogen-containing heterocyclic rings included in compound (A) is preferably 1 to 4, and more preferably 1 or 2. The number of monovalent organic groups R¹ included in compound (A) is preferably 1 to 4, and more preferably 1 or 2.

In terms of the point of being able to further improve the coatability of the surface modification composition containing water as a solvent and in terms of the point of being able to obtain a higher density film, compound (A) preferably has a structure in which the monovalent organic group R¹ is bonded to a nitrogen atom constituting the nitrogen-containing heterocyclic ring, or the monovalent organic group R¹ is bonded to a nitrogen atom that is bonded to the nitrogen-containing heterocyclic ring directly or via a divalent linking group. The divalent linking group in the latter case is preferably an alkanediyl group having 1 to 3 carbon atoms, and more preferably a methylene group. The nitrogen atom to which the monovalent organic group R¹ is bonded may be in a cationic form.

From the viewpoint of forming a higher density film, among these, compound (A) is preferably a compound having one nitrogen-containing heterocyclic ring in one molecule and having a structure in which the monovalent organic group R¹ is bonded to the nitrogen-containing heterocyclic ring directly or via a group having a nitrogen atom.

Preferred specific examples of compound (A) include a compound represented by the following formula (1), a compound represented by the following formula (2), and a compound represented by the following formula (3).

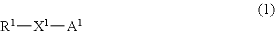

(In formula (1), R¹ is a monovalent hydrocarbon group having 4 to 40 carbon atoms, a halogenated hydrocarbon group having 4 to 40 carbon atoms, —R³—O—R^{6A}, or —CR⁴(OH)—R^{6A} (where R^{6A} is a monovalent hydrocarbon group having 4 to 40 carbon atoms). X¹ is a single bond or —NR²—. R² is a hydrogen atom or a methyl group. A¹ is a monovalent group having a nitrogen-containing heterocyclic ring. However, in the case of X¹ being a single bond, R¹ is directly bonded to the nitrogen-containing heterocyclic ring in A¹, and in the case of X¹ being —NR²—, X¹ is directly bonded to the nitrogen-containing heterocyclic ring in A¹.)

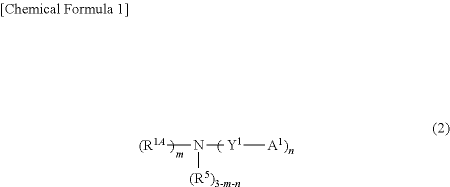

(In formula (2), R^{1A} is a monovalent hydrocarbon group having 4 to 40 carbon atoms. Y¹ is a single bond or an alkanediyl group having 1 to 3 carbon atoms. R⁵ is a hydrogen atom or a methyl group. A¹ is a monovalent group having a nitrogen-containing heterocyclic ring. However, in the case of Y¹ being a single bond, the nitrogen atom to which R^{1A} is bonded is directly bonded to the nitrogen-containing heterocyclic ring in A¹, and in the case of Y¹ being an alkanediyl group having 1 to 3 carbon atoms, Y¹ is directly bonded to the nitrogen-containing heterocyclic ring in A¹. m is 1 or 2, n is 1 or 2, and m+n≤3 is satisfied.)

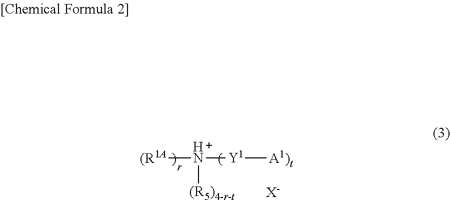

(In formula (3), R^{1A} is a monovalent hydrocarbon group having 4 to 40 carbon atoms. Y¹ is a single bond or an alkanediyl group having 1 to 3 carbon atoms. R⁵ is a hydrogen atom or a methyl group. A¹ is a monovalent group having a nitrogen-containing heterocyclic ring. However, in the case of Y¹ being a single bond, N⁺ to which R^{1A} is bonded is directly bonded to the nitrogen-containing heterocyclic ring in A¹, and in the case of Y¹ being an alkanediyl group having 1 to 3 carbon atoms, Y¹ is directly bonded to the nitrogen-containing heterocyclic ring in A¹. r is 1 or 2, t is 1 or 2, and r+t≤4 is satisfied. X⁻ is a counter anion.)

In the above formulas (1) to (3), specific examples and preferred examples of the groups represented by R¹ and R^{1A} include the same groups as the groups described as the monovalent organic group R¹ above.

Specific examples and preferred examples of the nitrogen-containing heterocyclic ring included in A¹ include the same nitrogen-containing heterocyclic rings as described above. A substituent (however, a group different from the group including the monovalent organic group R¹) may be bonded to the nitrogen-containing heterocyclic ring in A¹. Examples of the substituent bonded to the nitrogen-containing heterocyclic ring in A¹ include alkyl groups having 1 to 3 carbon atoms (methyl group, ethyl group, propyl group), acetyl group, formyl group, halogen atoms (fluorine atom, chlorine atom, bromine atom, iodine atom, etc.), nitro group, etc.

Examples of the counter anion of X⁻ include the same ones as the specific examples of counter ions in the case of being included in the form of nitrogen-containing heterocyclic ring salt.

Specific examples of compound (A) include 1-octylimidazole, 1-nonylimidazole, 1-decylimidazole, 1-undecylimidazole, 1-dodecylimidazole, 1-tridecylimidazole, 1-tetradecylimidazole, 1-pentadecylimidazole, 1-hexadecylimidazole, 1-octylbenzimidazole, 1-nonylbenzimidazole, 1-decylbenzimidazole, 1-undecylbenzimidazole, 1-dodecylbenzimidazole, 1-tridecylbenzimidazole, 1-tetradecylbenzimidazole, 1-pentadecylbenzimidazole, 1-hexadecylbenzimidazole, 1-octyl-4-methylpiperazine, 1-nonyl-4-methylpiperazine, 1-decyl-4-methylpiperazine, 1-undecyl-4-methylpiperazine, 1-dodecyl-4-methylpiperazine, 1-tridecyl-4-methylpiperazine, 1-tetradecyl-4-methylpiperazine, 1-pentadecyl-4-methylpiperazine, 1-dodecyl-4-ethylpiperazine, 1-tridecyl-4-ethylpiperazine, 1-nonyl-2-methylbenzimidazole, 1-dodecyl-2-methylbenzimidazole, 1-tridecyl-2-methylbenzimidazole, 1-dodecyl-2-ethylbenzimidazole, 1-tridecyl-2-ethylbenzimidazole, 1-dodecyl-6-methylbenzimidazole, 7-undecyl-1,5,7-triazabicyclo[4.4.0]dec-5-ene, 7-dodecyl-1,5,7-triazabicyclo[4.4.0]dec-5-ene, 7-tridecyl-1,5,7-triazabicyclo[4.4.0]dec-5-ene, 4-undecylamino-1-methylpiperidine, 4-dodecylamino-1-methylpiperidine, 4-tridecylamino-1-methylpiperidine, 2-(dodecylamino)pyridine, 2-(tridecylamino)pyridine, 3-(dodecylamino)pyridine, 3-(tridecylamino)pyridine, 4-(dodecylamino)pyridine, 4-(tridecylamino)pyridine, 1-dodecyl-4-formylimidazole, 1-undecyl-4-formylimidazole, 2-undecylimidazole, 2-dodecylimidazole, 2-tridecylimidazole, 1-undecyl-3-ethylimidazole bromide, 1-dodecyl-3-ethylimidazole bromide, 1-tridecyl-3-ethylimidazole bromide, 1-dodecyl-3-ethylimidazole chloride, 1-tridecyl-3-ethylimidazole chloride, 1-dodecyl-3-methylimidazole bromide, 1-tridecyl-3-methylimidazole bromide, N-((1H-benzo[d][1,2,3]triazol-1-yl)methyl)-N-octyloctane-1-amine, 1-((dodecyloxy)methyl)-1H-benzo[d][1,2,3]triazole, 1-(1H-benzo[d][1,2,3]triazol-1-yl)tridecan-1-ol, N-((1H-benzo[d][1,2,3]triazol-1-yl)methyl)-N,N-dimethylhexadecan-1-ammonium chloride, 1-dodecyl-1H-benzo[d][1,2,3]triazole N-((1H-benzo[d][1,2,3]triazol-1-yl)methyl)-N,N-dimethylhexadecan-1-ammonium benzotriazole, N-((1H-benzo[d][1,2,3]triazol-1-yl)methyl)-N,N-dimethylhexadecan-1-ammonium bromide, N-((1H-benzo[d][1,2,3]triazol-1-yl)methyl)-N,N-dimethylhexadecan-1-ammonium chloride, N-((1H-benzo[d][1,2,3]triazol-1-yl)methyl)-N,N-didodecanemethyl-1-ammonium chloride, N-((1H-benzo[d][1,2,3]triazol-1-yl)methyl)-N,N-didodecanemethyl-1-ammonium bromide, N,N-bis((1H-benzo[d][1,2,3]triazol-1-yl)methyl)-N,N-dodecane-1-ammonium chloride, N,N-bis((1H-benzo[d][1,2,3]triazol-1-yl)methyl)-N,N-dodecane-1-ammonium bromide, etc.

In the case of compound (A) being in a salt form, it is suitable in terms of the point that a monolayer can be formed on the substrate while removing components remaining on the substrate before formation of the monolayer by the surface modification composition. This enables the step of removing components remaining on the substrate before formation of the monolayer and the step of forming the monolayer to be carried out in one step, achieving simplification of processes in semiconductor manufacturing processes. From the viewpoint of enhancing the removal efficiency of components remaining on the substrate, the compound represented by the above formula (3) can be preferably used as compound (A).

The content of compound (A) in the surface modification composition is preferably 0.01% by mass or more, and more preferably 0.02% by mass or more, relative to the total amount of the surface modification composition, from the viewpoint of modifying the substrate surface with high density. In addition, from the viewpoint of modifying the substrate surface with high selectivity, the content of compound (A) in the surface modification composition is preferably 1.0% by mass or less, more preferably 0.5% by mass or less, and even more preferably 0.1% by mass or less, relative to the total amount of the surface modification composition.

### Solvent

The surface modification composition is an aqueous composition that contains water as a solvent component. The content of water in the surface modification composition is preferably 1% by mass or more, more preferably 5% by mass or more, even more preferably 10% by mass or more, still more preferably 20% by mass or more, and further preferably 40% by mass or more, relative to the total amount of the composition, from the viewpoint of ensuring the storage stability of the composition.

As the solvent component of the surface modification composition, water may be used alone, but an organic solvent may be further contained. By using a mixed solvent of water and an organic solvent as the solvent component of the surface modification composition, the storage stability of the surface modification composition can be enhanced. As the organic solvent, at least one selected from the group consisting of alcohols, ethers, ketones, sulfones, amides, cyclic amines, lactams, and esters can be preferably used.

Specific examples of organic solvent that may be blended in the surface modification composition include, as alcohols, for example, chain monoalcohols having 1 to 18 carbon atoms such as methanol, ethanol, propanol, isopropyl alcohol, 4-methyl-2-pentanol, and n-hexanol; alicyclic monoalcohols having 3 to 18 carbon atoms such as cyclohexanol; polyhydric alcohols having 2 to 18 carbon atoms such as 1,2-propylene glycol; and polyhydric alcohol partial ethers having 3 to 19 carbon atoms such as propylene glycol monomethyl ether (1-methoxy-2-propanol), 2-methoxy-1-propanol, ethylene glycol monomethyl ether, propylene glycol monomethyl ether, ethylene glycol monobutyl ether (butyl cellosolve), propylene glycol monoethyl ether, diethylene glycol monomethyl ether, diethylene glycol ethyl methyl ether, and diethylene glycol monobutyl ether.

Examples of ethers include tetrahydrofuran. Examples of ketones include acetone, methyl ethyl ketone, acetonyl acetone, and diacetone alcohol. Examples of sulfones include sulfolane and dimethyl sulfoxide. Examples of amides include cyclic amides such as N,N′-dimethylimidazolidinone and N-methylpyrrolidone; and chain amides such as N-methylformamide, N,N-dimethylformamide, N,N-diethylformamide, acetamide, N-methylacetamide, N,N-dimethylacetamide, and N-methylpropionamide. Examples of cyclic amines include morpholine and N-(3-aminopropyl)morpholine. Examples of lactams include 1-methyl-2-pyrrolidone. Examples of esters include, as chain esters, monocarboxylic acid esters such as ethyl lactate; and as cyclic esters, γ-butyrolactone and δ-valerolactone.

Among these organic solvents, alcohols are preferable in terms of the point of being easily miscible with water and further improving coatability of the surface modification composition, and in terms of the point of being able to form a higher density film in the case of using compound (A) as a film forming material. At least one selected from the group consisting of chain monoalcohols having 1 to 18 carbon atoms, polyhydric alcohols having 2 to 18 carbon atoms, and polyhydric alcohol partial ethers having 3 to 19 carbon atoms is more preferable, and polyhydric alcohol partial ethers having 3 to 19 carbon atoms are even more preferable. In addition, the number of carbon atoms of at least one compound selected from the group consisting of chain monoalcohols having 1 to 18 carbon atoms, polyhydric alcohols having 2 to 18 carbon atoms, and polyhydric alcohol partial ethers having 3 to 19 carbon atoms is preferably 1 to 15, more preferably 1 to 12, and even more preferably 1 to 10.

In the case of the surface modification composition including an organic solvent, the content of the organic solvent in the surface modification composition is preferably 65% by mass or less, more preferably 60% by mass or less, even more preferably 50% by mass or less, and still more preferably 40% by mass or less, relative to the total amount of the surface modification composition, from the viewpoint of minimizing the amount of organic solvent used as much as possible and from the viewpoint of enabling formation of a higher density film with compound (A). In addition, from the viewpoint of enhancing the storage stability of the surface modification composition, the content of the organic solvent in the surface modification composition is preferably 1% by mass or more, and more preferably 2% by mass or more, relative to the total amount of the surface modification composition.

The content of water in the surface modification composition is preferably 30% by mass or more, more preferably 35% by mass or more, even more preferably 45% by mass or more, still more preferably 55% by mass or more, further preferably 65% by mass or more, and still further preferably 70% by mass or more, relative to the total amount of water and organic solvent included in the surface modification composition, from the viewpoint of minimizing the amount of organic solvent used as much as possible.

### Other Components

The surface modification composition may further contain components (hereinafter also referred to as “other components”) different from compound (A) and the solvent component in addition to the above-described compound (A) and solvent component. In terms of the point of being able to enhance the storage stability of the surface modification composition, the surface modification composition preferably contains a pH adjuster together with compound (A) and water. The surface modification composition may also contain a cleaning component as other components.

### (pH Adjuster)

The pH adjuster is a component for adjusting the hydrogen ion concentration in the surface modification composition. The pH adjuster may be any of inorganic acids, organic acids, inorganic bases, and organic bases, and may be salts thereof. A buffer solution may also be used as the pH adjuster to be blended in the surface modification composition.

Specific examples of the pH adjuster include, as inorganic acids, phosphoric acid, boric acid, hydrochloric acid, sulfuric acid, nitric acid, etc.; as organic acids, acetic acid, lactic acid, malonic acid, succinic acid, citric acid, gluconic acid, cis-2-butenedioic acid, N-propylpiperazine-N′-ethanesulfonic acid, etc.; as inorganic bases, ammonia, potassium hydroxide, sodium hydroxide, etc.; and as organic bases, monoethanolamine, diethanolamine, triethanolamine, trimethylamine, triethylamine, propylamine, dibutylamine, etc. Examples of salts include salts of the acids or bases shown above which are compounds that exhibit buffering action, such as ammonium chloride, ammonium acetate, and sodium citrate. Examples of buffer solution include sodium phosphate buffer solution, sodium acetate buffer solution, sodium citrate phosphate buffer solution, sodium tartrate buffer solution, potassium borate buffer solution, sodium borate buffer solution, etc. The organic acids and organic bases used as the pH adjuster preferably have 10 or fewer carbon atoms, more preferably 8 or fewer carbon atoms, and even more preferably 7 or fewer carbon atoms.

From the viewpoint of minimizing the metal content in the surface modification composition as much as possible, among the above, the pH adjuster is preferably organic acid, organic base, or ammonia, and more preferably carboxy group-containing chain compound, chain monoamine compound, or ammonia. The carboxy group-containing chain compound preferably has 8 or fewer carbon atoms, and more preferably 2 to 7 carbon atoms. The chain monoamine compound preferably has 6 or fewer carbon atoms, and more preferably 2 to 4 carbon atoms.

Among the above, at least one selected from the group consisting of ammonia, monoethanolamine, diethanolamine, triethanolamine, citric acid, malonic acid, and cis-2-butenedioic acid can be preferably used as the pH adjuster.

In the case of blending a pH adjuster in the surface modification composition, the content of the pH adjuster in the surface modification composition may be any amount that enables adjustment of the surface modification composition to a desired pH, and can be appropriately set according to the type of pH adjuster used.

### (Cleaning Component)

For the purpose of removing components (for example, residues from dry etching for hole formation, etc.) remaining on the substrate before forming a monolayer on the substrate with the surface modification composition, a cleaning component may be blended in the surface modification composition. By blending the cleaning component together with compound (A), a monolayer composed of compound (A) can be formed on the substrate while removing components remaining on the substrate. This enables the step of removing components remaining on the substrate before formation of the monolayer and the step of forming the monolayer to be carried out in one step, which is suitable in terms of the point of achieving simplification of processes in the semiconductor manufacturing processes.

From the viewpoint of forming a higher density film on the substrate with compound (A) while sufficiently obtaining a cleaning effect on the substrate surface, the molecular weight of the cleaning component is preferably less than the molecular weight of compound (A). Specifically, the molecular weight of the cleaning component is preferably 300 or less, more preferably 200 or less, even more preferably 100 or less, and still more preferably 80 or less. In addition, the molecular weight of the cleaning component is preferably 10 or more, and more preferably 15 or more.

Examples of cleaning component include fluorine compound, hydrogen peroxide, citric acid, ethylenediaminetetraacetic acid (EDTA), or two or more of these. Specific examples of fluorine compound include hydrofluoric acid (hydrogen fluoride), ammonium fluoride, tetramethylammonium fluoride, hexafluorosilicic acid, etc. In terms of the point of a high cleaning effect, a fluorine compound can be preferably used as the cleaning component.

The content of the cleaning component in the surface modification composition is preferably 0.0001% by mass or more, more preferably 0.001% by mass or more, and even more preferably 0.005% by mass or more, relative to the total amount of the surface modification composition, from the viewpoint of sufficiently obtaining a cleaning effect on the substrate. In addition, from the viewpoint of not hindering the selective modification of the substrate surface with compound (A), the content of the cleaning component is preferably 10% by mass or less, more preferably 7% by mass or less, and even more preferably 5% by mass or less, relative to the total amount of the surface modification composition.

Other components that may be blended in the surface modification composition include antioxidants, etc. in addition to the above. The blending amounts of other components can be appropriately selected according to each component within a range that does not impair the effects of the disclosure.

The surface modification composition preferably has a small metal content in consideration of application to semiconductor manufacturing processes. Specifically, the total amount of sodium, potassium, and calcium included in the surface modification composition is preferably 50 ppm or less, more preferably 10 ppm or less, even more preferably 1,000 ppb or less, still more preferably 500 ppb or less, and further preferably 100 ppb or less. The metal content in the surface modification composition is a value measured by ICP mass spectrometry (ICP-MS).

The surface modification composition can be prepared by mixing compound (A), water, and other components blended as required, and dissolving compound (A), etc. in water. The solid content concentration of the surface modification composition (that is, the ratio of the total mass of components other than the solvent component in the surface modification composition to the total mass of the surface modification composition) is preferably 0.0001% by mass to 0.30% by mass, and more preferably 0.0002% by mass to 0.15% by mass, from the viewpoint of forming a high density film while ensuring good coatability.

### <Method for Selectively Modifying Substrate Surface>

Next, the method for selectively modifying a substrate surface, implemented using the above-described surface modification composition, will be described. The selective modification method includes a coating step of coating the surface modification composition on a surface of a substrate.

### Coating Step

### (Substrate)

A substrate having a first region and a second region having a different material from the first region on a surface layer can be preferably used as the substrate. The first region preferably has different adsorptivity of compound (A) from the second region due to having a different material from the second region. As an example, the first region is a region having higher adsorptivity of compound (A) than the second region. From the viewpoint of selectively and densely performing surface modification of the substrate with compound (A), the first region is preferably formed of a conductive material, and the second region is preferably formed of an insulating material. Further, the substrate to be selectively modified with the surface modification composition preferably has a first region formed of a conductive material and a second region formed of an insulating material.

In the case of the first region being a region formed of a conductive material, the first region includes a metal element. For example, the metal element is at least one selected from the group consisting of copper, iron, zinc, cobalt, aluminum, titanium, tin, tungsten, zirconium, tantalum, germanium, molybdenum, ruthenium, gold, silver, platinum, palladium, and nickel. The metal element included in the first region may be a simple metal, and may be an alloy (nickel-copper alloy, cobalt-nickel alloy, gold-silver alloy, etc.), a conductive nitride (tantalum nitride, titanium nitride, etc.), or the like. Among these, the first region preferably includes a simple metal, an alloy, or a conductive nitride, and more preferably includes at least one selected from the group consisting of copper, cobalt, tungsten, tantalum, titanium, and ruthenium.

When performing surface treatment of a substrate with the surface modification composition, the type of compound (A) included in the surface modification composition may be appropriately selected according to the metal species included in the first region. In the case of compound (A) having a nitrogen-containing aromatic heterocyclic ring, from the viewpoint of forming a high density film on the substrate surface with high selectivity, the first region preferably includes at least one selected from the group consisting of tungsten, cobalt, copper, molybdenum, and ruthenium, and more preferably includes at least one selected from the group consisting of tungsten, cobalt, and copper. Further, in the case of the first region including at least one selected from the group consisting of tungsten, cobalt, copper, molybdenum, and ruthenium, the nitrogen-containing aromatic heterocyclic ring included in compound (A) is preferably imidazole ring, pyrazole ring, triazole ring, pyridine ring, benzimidazole ring, or benzotriazole ring, and more preferably imidazole ring, pyridine ring, benzimidazole ring, or benzotriazole ring.

In the case of compound (A) having a nitrogen-containing non-aromatic heterocyclic ring, the first region preferably includes at least one selected from the group consisting of copper, cobalt, and ruthenium. Further, in the case of the first region including at least one selected from the group consisting of copper, cobalt, and ruthenium, the nitrogen-containing non-aromatic heterocyclic ring included in compound (A) is preferably piperidine ring, piperazine ring, hexamethyleneimine ring, Diazabicycloundecene, or 1,5,7-triazabicyclo[4.4.0]deca-5-ene, and more preferably piperidine ring, piperazine ring, or 1,5,7-triazabicyclo[4.4.0]deca-5-ene.

In the case of the second region being a region formed of an insulating material, the second region is formed of, for example, silicon-containing compounds such as silicon oxide, silicon nitride, silicon oxynitride, and silicide (for example, SiO₂, SiOC, Si₃N₄, SiNx, SiON, SiC, SiOCN, etc.) or metal oxides (for example, alumina, tantalum oxide, etc.). The second region preferably includes silicon oxide, silicon nitride, silicon oxynitride, silicide, or metal oxide.

In particular, in the case of the substrate on which the surface modification composition is coated having, as the first region, a region including at least one selected from the group consisting of copper, cobalt, tungsten, tantalum, titanium, molybdenum, and ruthenium, and having, as the second region, a region including silicon oxide, silicon nitride, silicon oxynitride, or metal oxide, it is suitable in terms of the point that compound (A) can be adsorbed to the first region, among the first region and the second region, with high selectivity and high density.

The shape of the coated surface on the substrate is not particularly limited. The coated surface may be, for example, planar, arc-shaped, recessed, protruding, or the like. Further, in the case of the coated surface having the first region and the second region, the arrangement form of the first region and the second region is not particularly limited, either. For example, the first region and the second region may be arranged in a predetermined direction on a plane in a state where the first region and the second region are adjacent to each other. Alternatively, within one region of the first region and the second region, several of the other region may be arranged. Further, one of the first region and the second region may constitute the bottom surface of a hole or groove formed in the substrate, and the other may constitute the side surface thereof.

The substrate surface on which the film forming composition is coated may be subjected to pretreatment such as plasma treatment using, for example, H₂, mixed gas of N₂ and H₂, O₂ gas, etc., cleaning treatment of the substrate surface, and wet modification treatment.

### (Coating Method)

Examples of methods for coating the surface modification composition include spray method, roll coating method, spin coating method, slit die coating method, bar coating method, inkjet method, etc. Among these, it is preferable to coat the surface modification composition on the substrate surface by spin coating method, slit die coating method, or bar coating method. The film thickness of the coating film formed on the substrate can be appropriately set so that the film finally formed on the substrate has a desired thickness.

By coating the surface modification composition on the surface of the substrate through the coating step, a film (specifically, monolayer) of compound (A) is formed on the first region. After coating the surface modification composition on the substrate surface, the solvent component in the surface modification composition may be removed by natural drying, thereby forming a film on the first region. Further, heat treatment for removing the solvent component from the surface modification composition coated on the substrate surface may be performed. The heat treatment can be performed using a heating device such as an oven or a hot plate. The heating temperature is, for example, 40° C. or higher, and may be 50° C. or higher. The heating time is, for example, 0.5 minutes to 60 minutes. Compound (A) has high adsorption ability to metal and can form a film in the first region without performing heat treatment, which is suitable in terms of the point of achieving simplification of the manufacturing processes. The thickness of the film formed on the substrate is, for example, several nm (for example, about 0.5 nm to 20 nm).

The selective modification method preferably further includes a step of removing components derived from the surface modification composition on the second region by bringing the surface of the substrate into contact with a rinse solution after coating the surface modification composition in the above-described coating step, thereby cleaning the substrate surface (hereinafter also referred to as “cleaning step”). In the case where components derived from the surface modification composition (more specifically, the composition itself, compound (A), residual film formed by the composition, etc.) remain as residues on the second region, the residues can be removed from the second region through this cleaning step. Thereby, the region of the substrate surface to be protected can be more highly selectively covered with the film formed by compound (A), and the substrate surface can be selectively protected.

### Cleaning Step

An organic solvent can be preferably used as the rinse solution. Examples of organic solvent include propylene glycol monomethyl ether acetate, isopropanol, acetone, methyl ethyl ketone, methyl-n-propyl ketone, and mixed solvents of two or more of these.

The components derived from the surface modification composition on the second region are removed from the second region with the rinse solution by bringing the substrate surface after the above coating step into contact with the rinse solution. The method for bringing the substrate surface into contact with the rinse solution is not particularly limited, and for example, shower method, spray method, dip (immersion) method, puddle method, etc. can be applied. When bringing the substrate surface into contact with the rinse solution, for example, the treatment of supply and contact of the rinse solution onto the substrate may be performed multiple times, or the rinse solution or the substrate may be shaken. The temperature of the rinse solution when bringing the substrate surface into contact with the rinse solution is, for example, 5° C. to 50° C. The contact time is, for example, 5 seconds to 30 minutes. The amount of rinse solution used can be appropriately set in consideration of the contact method between the substrate surface and the rinse solution, etc. After bringing the substrate surface into contact with the rinse solution, the rinse solution on the substrate may be removed using a spin coater or the like.

With the method including the above coating step and optionally including the cleaning step, a substrate surface-treated with the composition containing compound (A) and water can be obtained. That is to say, according to the disclosure, a method is provided for producing a surface-treated substrate, which includes a step of coating a composition on a surface of a substrate to selectively modify the surface of the substrate.

By performing the method including the coating step and the cleaning step described above, the substrate surface can be surface-modified with high selectivity and high density through simple treatment. Each treatment of the following steps (contact step, metal layer formation step, film removal step), for example, may be further performed on the substrate obtained by the coating step and the optionally included cleaning step.

### Contact Step

The contact step is a step of bringing alcohol, dilute acid, hydrogen peroxide water, ozone, plasma, ammonia, or ammonium fluoride salt aqueous solution into contact with the substrate surface after forming a film on the first region by the coating step (preferably after contact with the rinse solution through the cleaning step). In the manufacturing processes of semiconductors, etc., an oxide film layer may be formed on the contact surface with air (on the second region) on the substrate surface due to exposure of the substrate surface to air. Therefore, by providing such a contact step, the oxide film layer formed on the second region can be removed. Among the above, examples of dilute acid include dilute hydrochloric acid, dilute sulfuric acid, dilute citric acid, dilute oxalic acid, dilute maleic acid, dilute acetic acid, dilute isobutyric acid, dilute 2-ethylhexanoic acid, etc.

### Metal Layer Formation Step

The metal layer formation step is a step of forming a metal layer on the second region after forming a film on the first region by the coating step (preferably after contact with the rinse solution through the cleaning step, and more preferably after the contact step). The first region, among the substrate surface after the cleaning step, is covered with a protective film (monolayer) formed by compound (A). Therefore, when forming a metal layer by the metal layer formation step, the metal layer can be selectively formed on the second region among the first region and the second region. The method for forming the metal layer is not particularly limited, but from the viewpoint of performing pattern formation with high selectivity on fine regions, it is preferable to form a metal pattern by chemical vapor deposition (CVD) method or atomic layer deposition (ALD) method. The metal layer formed on the second region may be a barrier layer for separating metal portions and insulating portions or for suppressing diffusion of metal from the metal portions. The thickness of the metal layer can be appropriately set according to the application of the substrate, etc., but is, for example, 1 nm to 30 nm.

### Film Removal Step

The film removal step is a step of removing the film formed on the first region after forming the metal layer on the second region by the metal layer formation step. The removal of the film can be performed by etching. Examples of etching method include known methods such as reactive ion etching (RIE) and physical etching. Examples of reactive ion etching include chemical dry etching using CF₄, O₂ gas, etc. and utilizing the difference in etching rate of each layer; chemical wet etching (wet development) using liquid etching solution such as organic solvent and hydrofluoric acid; etc. Examples of physical etching include sputter etching and ion beam etching. Among these, reactive ion etching is preferable, and chemical dry etching or chemical wet etching is more preferable.

Examples of solvent used in chemical wet etching include acetic acid, APM (a mixture of ammonia, hydrogen peroxide solution, and water), SPM (a mixture of sulfuric acid and hydrogen peroxide solution), 2.38% by mass TMAH aqueous solution, dilute hydrofluoric acid, water, etc.

By implementing the above steps (coating step, cleaning step, contact step, metal layer formation step, and film removal step), a substrate can be obtained in which a metal layer is selectively formed on the second region, and for the first region, the surface of the first region (for example, metal surface) is in an exposed state. The obtained substrate may be further subjected to various treatments such as plating treatment. In the case of performing plating treatment, the plating method is not particularly limited, and known electroplating, electroless plating, hot-dip plating, vacuum plating, vapor phase plating, etc. can be employed. In the case of application to semiconductor manufacturing processes, among these, electroplating or electroless plating is preferable. After the plating treatment, planarization treatment (CMP treatment) of the substrate surface may be performed as required.

According to the disclosure described above, the following means are provided.

[Means 1]A method for selectively modifying a substrate surface, including: a step of coating a composition on a surface of a substrate, in which the composition includes a compound (A), which has a nitrogen-containing heterocyclic ring and a monovalent organic group having 4 or more carbon atoms, and water.

[Means 2] The method for selectively modifying the substrate surface according to [Means 1], in which the substrate includes a first region and a second region having a different material from the first region, and a film is formed on the first region by coating the composition on the surface of the substrate including the first region and the second region.

[Means 3] The method for selectively modifying the substrate surface according to [Means 2], in which the first region is formed of a conductive material, and the second region is formed of an insulating material.

[Means 4] The method for selectively modifying the substrate surface according to [Means 2] or [Means 3], further including: a step of removing components derived from the composition on the second region by bringing the surface of the substrate into contact with a rinse solution after coating the composition.

[Means 5] The method for selectively modifying the substrate surface according to [Means 4], further including: a step of bringing alcohol, dilute acid, hydrogen peroxide water, ozone, plasma, ammonia, or ammonium fluoride salt aqueous solution into contact with the substrate surface after contact with the rinse solution.

[Means 6] The method for selectively modifying the substrate surface according to [Means 4] or [Means 5], further including: a step of forming a metal layer on the second region after contact with the rinse solution.

[Means 7] The method for selectively modifying the substrate surface according to [Means 6], further including: a step of removing the film on the first region formed by the composition after formation of the metal layer.

[Means 8] The method for selectively modifying the substrate surface according to any one of [Means 1] to [Means 7], in which the monovalent organic group having 4 or more carbon atoms, which is included in the compound (A), is bonded to a nitrogen atom constituting the nitrogen-containing heterocyclic ring, or is bonded to a nitrogen atom that is bonded to the nitrogen-containing heterocyclic ring directly or via a divalent linking group.

[Means 9] The method for selectively modifying the substrate surface according to any one of [Means 1] to [Means 8], in which the composition further includes a pH adjuster.

[Means 10] The method for selectively modifying the substrate surface according to [Means 9], in which the pH adjuster is an organic acid, an organic base, or ammonia.

[Means 11] The method for selectively modifying the substrate surface according to [Means 9] or [Means 10], in which the pH adjuster is a carboxy group-containing chain compound, a chain monoamine compound, or ammonia.

[Means 12] The method for selectively modifying the substrate surface according to any one of [Means 1] to [Means 11], in which the monovalent organic group having 4 or more carbon atoms, which is included in the compound (A), is a monovalent hydrocarbon group having 4 or more carbon atoms, a monovalent halogenated hydrocarbon group having 4 or more carbon atoms, —R³—O—R⁶ or —CR⁴(OH)—R⁶ (where R³ is an alkanediyl group having 1 to 3 carbon atoms, R⁴ is a hydrogen atom or a methyl group, and R⁶ is a monovalent hydrocarbon group having 4 or more carbon atoms).

[Means 13] The method for selectively modifying the substrate surface according to any one of [Means 1] to [Means 12], in which the monovalent organic group having 4 or more carbon atoms, which is included in the compound (A), is a monovalent chain hydrocarbon group having 4 or more carbon atoms, —R³—O—R⁷ or —CR⁴(OH)—R⁷ (where R³ is an alkanediyl group having 1 to 3 carbon atoms, R⁴ is a hydrogen atom or a methyl group, and R⁷ is a monovalent chain hydrocarbon group having 4 or more carbon atoms).

[Means 14] The method for selectively modifying the substrate surface according to any one of [Means 1] to [Means 13], in which the composition further includes an organic solvent, and a content of the organic solvent in the composition is 60% by mass or less relative to a total amount of the composition.

[Means 15] The method for selectively modifying the substrate surface according to [Means 14], in which the organic solvent included in the composition is at least one selected from a group consisting of alcohols, ethers, ketones, sulfones, amides, cyclic amines, lactams, and esters.

[Means 16] The method for selectively modifying the substrate surface according to any one of [Means 1] to [Means 15], in which a content of the water is 10% by mass or more relative to a total amount of the composition.

[Means 17] The method for selectively modifying the substrate surface according to any one of [Means 1] to [Means 16], in which the composition further includes a cleaning component.

[Means 18] The method for selectively modifying the substrate surface according to [Means 17], in which the cleaning component is a fluorine compound.

[Means 19] A method for producing a surface-treated substrate, including: a step of coating a composition on a surface of a substrate to selectively modify the surface of the substrate, in which the composition includes a compound (A), which has a nitrogen-containing heterocyclic ring and a monovalent organic group having 4 or more carbon atoms, and water.

[Means 20] A composition, used for selectively modifying a substrate surface, the composition including: a compound (A), which has a nitrogen-containing heterocyclic ring and a monovalent organic group having 4 or more carbon atoms; and water.

[Means 21] The composition according to [Means 20], in which the monovalent organic group having 4 or more carbon atoms, which is included in the compound (A), is bonded to a nitrogen atom constituting the nitrogen-containing heterocyclic ring, or is bonded to a nitrogen atom that is bonded to the nitrogen-containing heterocyclic ring directly or via a divalent linking group.

[Means 22] The composition according to [Means 20] or [Means 21], further including a pH adjuster.

[Means 23] The composition according to any one of [Means 20] to [Means 22], in which the monovalent organic group having 4 or more carbon atoms, which is included in the compound (A), is a monovalent hydrocarbon group having 4 or more carbon atoms, a monovalent halogenated hydrocarbon group having 4 or more carbon atoms, —R³—O—R⁶ or —CR⁴(OH)—R⁶ (where R³ is an alkanediyl group having 1 to 3 carbon atoms, R⁴ is a hydrogen atom or a methyl group, and R⁶ is a monovalent hydrocarbon group having 4 or more carbon atoms).

[Means 24] The composition according to any one of [Means 20] to [Means 23], further including an organic solvent, in which a content of the organic solvent is 60% by mass or less relative to a total amount of the composition.

### EXAMPLES

Hereinafter, the disclosure will be specifically described based on examples, but the disclosure is not limited to these examples. The measurement method for each physical property value is shown below.

### <Synthesis of Compound (A)>

### [Synthesis Example 1] Synthesis of 1-dodecylimidazole (Compound (A-2))

To a 100 mL three-necked flask, 1.70 g (25 mmol) of imidazole, 6.3 g (25 mmol) of 1-bromododecane, 6.9 g (50 mmol) of potassium carbonate, and 50 mL of acetone were added, and the mixture was stirred at 72° C. for 7 hours under reflux in nitrogen atmosphere. The mixture was returned to room temperature and washed with ethyl acetate/pure water three times. The organic layer was recovered, dehydrated with anhydrous sodium sulfate, the filtrate was recovered through pleated filter paper, and concentrated under reduced pressure with an evaporator.

Purification was performed by column chromatography using only ethyl acetate (Rf 0.2). The solvent was distilled off with an evaporator and an oil pump, and the structure was confirmed by ¹H-NMR and ¹³C-NMR.

¹H NMR (CDCl₃, 400 MHz); δ 7.45 (s, 1H, imidazole ring), 7.05 (s, 1H, imidazole ring), 6.90 (s, 1H, imidazole ring), 3.96-3.90 (q, 2H, CH₂), 2.04-1.75 (m, 2H, CH₂), 1.30-1.25 (br, 20H, CH₂), 0.90 (t, 3H, CH₃).

¹³C NMR (CDCl₃, 100 MHz); δ 137.1 (imidazole ring), 129.4 (imidazole ring), 118.8 (imidazole ring), 47.1, 31.9, 31.2, 29.7, 29.6, 29.5, 29.4, 29.1, 26.6, 22.8 (CH₂), 14.2 (CH₃).

### [Synthesis Examples 2 to 10] Synthesis of Compound (A-1), Compound (A-3) to Compound (A-9), and Compound (A-11)

1-Dodecyl-3-ethylimidazole bromide (compound (A-1)) was derived by quaternary salt formation of 1-dodecylimidazole and bromoethane.

1-Dodecylbenzimidazole (compound (A-3)), 1-dodecyl-4-methylpiperazine (compound (A-4)), 1-dodecyl-2-methylbenzimidazole (compound (A-5)), 7-dodecyl-1,5,7-triazabicyclo[4.4.0]dec-5-ene (compound (A-6)), 4-dodecylamino-1-methylpiperidine (compound (A-7)), 1-dodecyl, 4-(tridecylamino)pyridine (compound (A-8)), and 1-dodecyl-4-formylimidazole (compound (A-9)) were derived by SN2 reaction with alkyl halides corresponding to the target product.

3,3,4,4,5,5,6,6,7,7,8,8,11,11,12,12,13,13,14,14,15,15,16,16,16-pentacosafluoro-9-hexadecen-1-ylphosphonic acid (compound (A-li)) was synthesized with reference to Japanese Patent Application Laid-Open No. 2022-00497.

2-Undecylimidazole (compound (A-10)) and 2-methylimidazole (compound (A-12)) were obtained from Tokyo Chemical Industry.

### [Synthesis Example 11] Synthesis of Compound (A-13): N-((1H-benzo[d][1,2,3]triazol-1-yl)methyl)-N-octyloctan-1-amine

To a 100 ml three-necked flask, 5.96 g (50 mmol) of benzotriazole, 4.87 g (60 mmol) of 37% formaldehyde, and 60 g of methanol were added, and the mixture was stirred for 30 minutes under ice cooling. A mixed solution of 12.1 g (50 mmol) of dioctylamine and 8.7 g of methanol was slowly added dropwise over 30 minutes. After completion of the dropwise addition, the mixture was returned to room temperature and stirred for 2 hours.

After completion of the reaction, the mixture was washed with methylene chloride/ultrapure water three times, the organic layer was recovered, dehydrated with anhydrous sodium sulfate, and the filtrate was recovered and concentrated. The concentrate was purified by column chromatography with ethyl acetate/n-hexane=1/1 vol %. After concentration, 6.2 g of a colorless transparent liquid was obtained. The obtained colorless transparent liquid compound was designated as compound (A-13).

The structure confirmation results by ¹H-NMR and ¹³C-NMR are as follows.

¹H NMR (400 MHz) δ; 8.07-8.05 (1H, m, Ph), 7.62-7.60 (1H, m, Ph), 7.50-7.46 (1H, m, Ph), 7.38-7.34 (1H m, Ph), 5.49 (2H, s, CH₂), 2.64-2.56 (2H, m, CH₂), 1.55-1.51 (4H, br, CH₂), 1.30-1.26 (20H, br, CH₂), 0.89 (6H, m, CH₃).

¹³C NMR (100 MHz) δ; 145.5, 132.8, 119.6, 126.2, 110.0, 75.2, 54.6, 31.9, 29.3, 28.0, 27.3, 22.7, 14.1

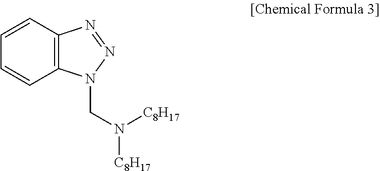

### [Synthesis Example 12] Synthesis of Compound (A-14): 1-((dodecyloxy)methyl)-1H-benzo[d][1,2,3]triazole

To a 100 ml three-necked flask, 4.47 g (30 mmol) of methylolbenzotriazole, 9.72 (39 mmol) of bromododecane, 4.98 g (36 mmol) of potassium carbonate, and 38.3 g of DMF were added, and the mixture was heated and stirred at 85° C. for 12 hours under nitrogen atmosphere.

After completion of the reaction, methylene chloride/ultrapure water and a small amount of saturated aqueous ammonium chloride solution were added, and washing was performed three times. The organic layer was dried with anhydrous sodium sulfate, then concentrated and purified by column chromatography with methylene chloride alone. After concentration, 5.7 g of white solid was obtained. The obtained white solid was designated as compound (A-14).

The structure confirmation results by ¹H-NMR and ¹³C-NMR are as follows.

¹H NMR (400 MHz) δ; 8.00 (1H, m, Ph), 7.75 (1H, m, Ph), 7.47 (1H, m, Ph), 7.36 (1H, m, Ph), 5.81 (2H, s, CH₂), 3.35 (2H, m, CH₂), 1.50 (2H, m, CH₂), 1.43 (2H, m, CH₂), 1.30-1.26 (16H, m, CH₂), 0.90 (3H, t, CH₃).

¹³C NMR (400 MHz) δ; 146.2, 132.0, 126.2, 119.6, 110.0, 79.5, 69.8, 31.9, 29.7, 29.6, 29.3, 29.2, 22.7, 14.1.

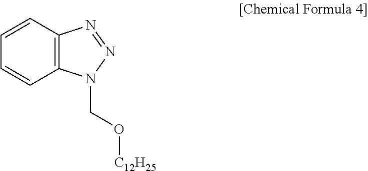

### [Synthesis Example 13] Synthesis of Compound (A-15): 1-(1H-benzo[d][1,2,3]triazol-1-yl)tridecan-1-ol

To a 100 ml three-necked flask, 5.96 g (50 mmol) of benzotriazole, 9.26 g (50 mmol) of decanal, and 30 g of diisopropyl ether were added, and the mixture was stirred at room temperature under nitrogen atmosphere. As the reaction proceeded, a precipitate was formed. After 6 hours, white solid was collected with a Buchner funnel while washing with diisopropyl ether. After drying, 8.6 g of white solid was obtained. The obtained white solid was designated as compound (A-15).

The structure confirmation results by ¹H-NMR and ¹³C-NMR are as follows.

¹H NMR (400 MHz) δ 8.00 (1H, m, Ph), 7.75 (1H, m, Ph), 7.47 (1H, m, Ph), 7.36 (1H, m, Ph), 5.70 (1H, d, CH), 4.52 (1H, br, OH), 1.90 (2H, m, CH₂), 1.27-1.25 (18H, m, CH₂), 0.88 (3H, t, CH₃).

¹³C NMR (400 MHz) δ; 144.7, 133.3, 126.2, 119.6, 93.1, 34.2, 31.9, 29.6, 29.3, 22.7, 20.8, 14.1.

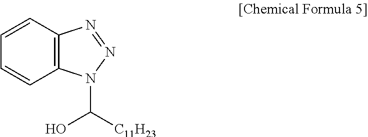

### [Synthesis Example 14] Synthesis of Compound (A-16): N-((1H-benzo[d][1,2,3]triazol-1-yl)methyl)-N,N-dimethylhexadecan-1-ammonium Chloride

To a 100 ml eggplant-shaped flask, 5.03 g (30 mmol) of 1-chloromethylbenzotriazole and 9.70 g (33 mmol) of dimethyldodecylamine were added, and the mixture was heated and stirred in acetonitrile at 85° C. for 6 hours. After cooling to room temperature, 150 ml of methanol and 200 ml of hexane were added, and liquid-liquid washing was performed three times. The methanol layer was collected and concentrated to obtain the target product. After drying, 13.3 g was obtained as white solid. The obtained white solid was designated as compound (A-16).

The structure confirmation results by ¹H-NMR and ¹³C-NMR are as follows.

¹H NMR (400 MHz) δ; 8.81 (1H, d, Ph), 8.06 (1H, d, Ph), 7.69-7.66 (1H, m, Ph), 7.47-7.43 (1H, m, Ph), 7.02 (2H, s, CH₂), 3.66 (2H, m, CH₂), 3.53 (6H, s, CH₃), 1.91 (2H, br, CH₂), 1.34-1.23 (28H, m, CH₂), 0.90 (3H, t, CH₃).

¹³C NMR (400 MHz) δ; 145.4, 134.8, 130.5, 125.6, 120.1, 111.6, 70.0, 63.2, 50.6, 48.9, 32.0, 29.7, 29.6, 29.5, 29.4, 29.2, 26.3, 22.8, 22.7, 14.2.

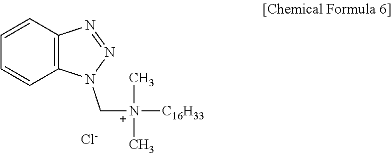

### [Synthesis Example 15] Synthesis of Compound (A-17): 1-dodecyl-1H-benzo[d][1,2,3]triazole

Compound (A-17) was synthesized with reference to Chemistry of Materials, 2010, 22, 4034.

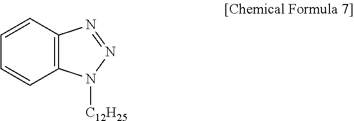

### [Synthesis Example 16] Synthesis of Compound (A-18): N-((1H-benzo[d][1,2,3]triazol-1-yl)methyl)-N,N-dimethylhexadecan-1-ammonium Benzotriazole

To a 100 ml eggplant-shaped flask, 6.02 g (15 mmol) of N-((1H-benzo[d][1,2,3]triazol-1-yl)methyl)-N,N-dimethylhexadecan-1-ammonium chloride, 2.12 g (15 mmol) of sodium benzotriazole, 100 ml of methylene chloride, and 100 ml of DIW (ultrapure water) were added, and the mixture was stirred at room temperature for 6 hours. After completion of the reaction, washing with water was performed three times, the organic layer was recovered, dried with anhydrous sodium sulfate, and concentrated with an evaporator. The obtained white solid was purified by column chromatography using an eluent of methylene chloride/methanol=10/1 vol %, the organic solvent was concentrated, and white solid (6.10 g) was obtained.

The structure confirmation results by ¹H-NMR and ¹³C-NMR are as follows.

¹H NMR (400 MHz) δ; 8.39 (d, 1H, Ph), 8.02 (d, 1H, Ph), 7.86 (d, 2H, Ph), 7.51 (m, 1H, Ph), 7.41 (m, 1H, Ph), 7.27 (d, 2H, Ph), 6.92 (s, 2H, CH₂), 3.31 (br, 8H, CH₂, CH₃), 1.68 (br, 2H, CH₂), 1.67-1.18 (br, 26H, CH₂), 0.88 (t, 3H, CH₃).

¹³C NMR (100 MHz) δ; 145.3, 134.7, 130.4, 125.5, 121.8, 120.1, 116.4, 111.1, 69.9, 63.0, 48.8, 32.0, 29.8, 29.6, 29.5, 29.4, 29.3, 29.1, 26.2, 22.7, 22.5, 14.2.

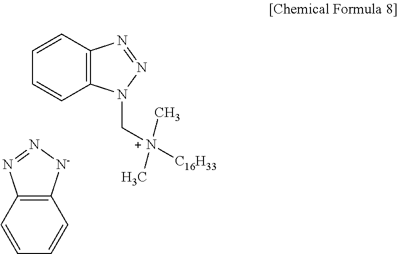

### [Synthesis Example 17] Synthesis of Compound (A-19): N-((1H-benzo[d][1,2,3]triazol-1-yl)methyl)-N,N-didodecylmethyl-1-ammonium Bromide

To a 100 ml eggplant-shaped flask, 4.48 g (30 mmol) of 1-hydroxymethylbenzotriazole and 9.48 g (35 mmol) of phosphorus tribromide were added, and the mixture was stirred in toluene at room temperature for 3 hours. After removing toluene with an evaporator, 50 ml of cold water was added, and further, 2M NaOH aqueous solution was added until the pH approached 11. Next, extraction with methylene chloride was performed twice. The mixture was dried with anhydrous sodium sulfate, the solvent was removed with an evaporator, and purification was performed by column chromatography with methylene chloride to obtain 5.8 g of 1-(bromomethyl)-1H-benzo[d][1,2,3]triazole.

Next, to a 100 ml eggplant flask, 6.36 g (30 mmol) of 1-(bromomethyl)-1H-benzo[d][1,2,3]triazole, 11.0 g (30 mmol) of didodecylmethylamine, and 30 ml of acetonitrile were added, and the mixture was stirred for 8 hours under heating and reflux. After cooling to room temperature, 150 ml of methanol and 200 ml of hexane were added, and liquid-liquid washing was performed three times. The methanol layer was recovered and concentrated to obtain the target product. After drying, 15.1 g of white solid was obtained. This was designated as compound (A-19).

The structure confirmation results by ¹H-NMR and ¹³C-NMR are as follows.

¹H NMR (400 MHz) δ; 8.00 (1H, d, Ph), 7.75 (1H, d, Ph), 7.36 (1H, m, Ph), 7.47 (1H, m, Ph), 5.68 (2H, s, CH₂), 3.30 (4H, m, CH₂), 3.22 (3H, s, CH₃), 1.71 (4H, br, CH₂), 1.30-1.26 (38H, m, CH₂), 0.88 (6H, t, CH₃).

¹³C NMR (400 MHz) δ; 145.5, 132.8, 126.2, 126.1, 119.6, 110.0, 91.3, 60.0, 59.9, 50.6, 47.8, 31.9, 29.6, 29.3, 26.8, 22.7, 14.1.

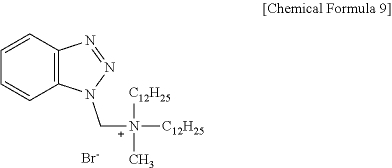

### [Synthesis Example 18] Synthesis of Compound (A-20): N,N-bis((1H-benzo[d][1,2,3]triazol-1-yl)methyl)-N,N-dodecan-1-ammonium bromide

To a 100 ml eggplant-shaped flask, 4.48 g (30 mmol) of 1-hydroxymethylbenzotriazole and 9.48 g (35 mmol) of phosphorus tribromide were added, and the mixture was stirred in toluene at room temperature for 3 hours. After removing toluene with an evaporator, 50 ml of cold water was added, and further, 2M NaOH aqueous solution was added until the pH approached 11. Next, extraction with methylene chloride was performed twice. The mixture was dried with anhydrous sodium sulfate, the solvent was removed with an evaporator, and purification was performed by column chromatography with methylene chloride to obtain 5.8 g of 1-(bromomethyl)-1H-benzo[d][1,2,3]triazole.

Next, to a 100 ml eggplant flask, 4.24 g (20 mmol) of 1-(bromomethyl)-1H-benzo[d][1,2,3]triazole, 9.56 g (10 mmol) of didodecylamine, and 30 ml of acetonitrile were added, and the mixture was stirred for 8 hours under heating and reflux. After cooling to room temperature, 150 ml of methanol and 200 ml of hexane were added, and liquid-liquid washing was performed three times. The methanol layer was recovered and concentrated, the flask was immersed in dry ice acetone for crystallization, and then slurry washing was performed with ethyl acetate. This slurry was recovered with a Buchner funnel, and after drying, 9.6 g of white solid was obtained. This was designated as compound (A-20).

The structure confirmation results by ¹H-NMR and ¹³C-NMR are as follows.

¹H NMR (400 MHz) δ; 7.96 (d, 2H, Ph), 7.67 (d, 2H, Ph), 7.39-7.36 (m, 4H, Ph), 4.80 (s, 4H, CH₂), 2.4 (br, 2H, CH₂), 2.34 (br, 2H, CH₂), 1.36-1.26 (br, 40, CH₂), 0.89 (t, 6H, CH₃).

¹³C NMR (100 MHz) δ; 145.5, 132.8, 126.2, 119.6, 110.0, 88.0, 61.0, 50.0, 32.1, 31.9, 30.8, 29.6, 29.3, 27.6, 25.2, 22.7, 21.0, 14.1.

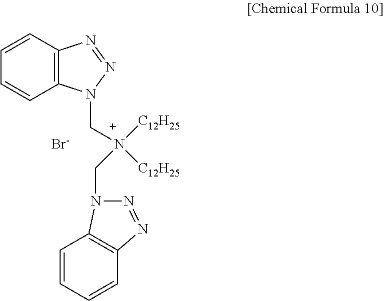

The structural formulas of compound (A-1) to compound (A-20) are shown below.

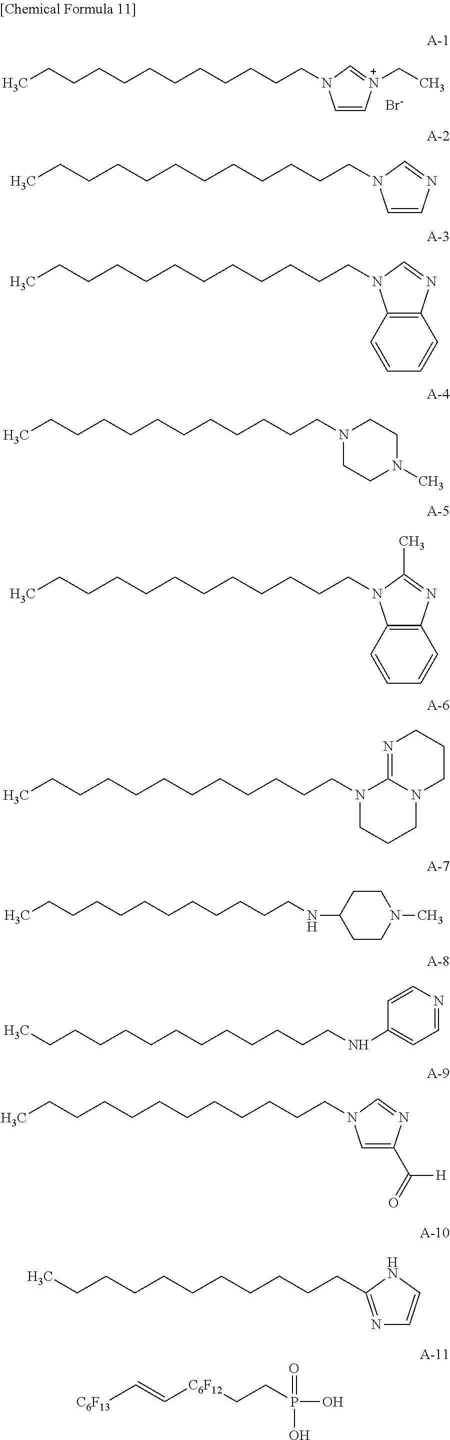

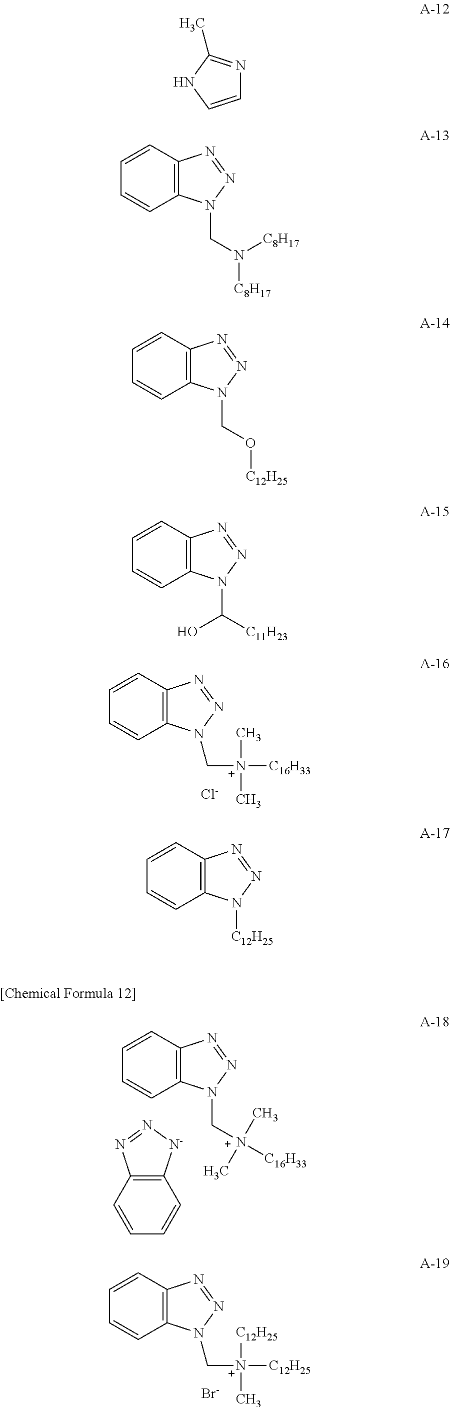

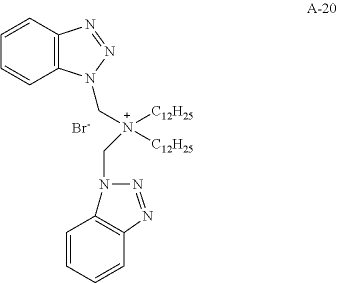

### <Preparation of Surface Modification Composition>

Each component used in the preparation of the surface modification composition is as follows.

### Low Molecular Weight Compound

A-1 to A-20: the above-described compounds (A-1) to (A-20)
A-21: Emal 0 (manufactured by Kao Corporation, anionic surfactant, sodium lauryl sulfate)
   (B) pH adjuster
B-1: monoethanolamine
B-2: 25% ammonia aqueous solution
B-3: citric acid
B-4: malonic acid
B-5: cis-2-butenedioic acid
B-6: potassium hydroxide
B-7: N-propylpiperazine-N′-ethanesulfonic acid

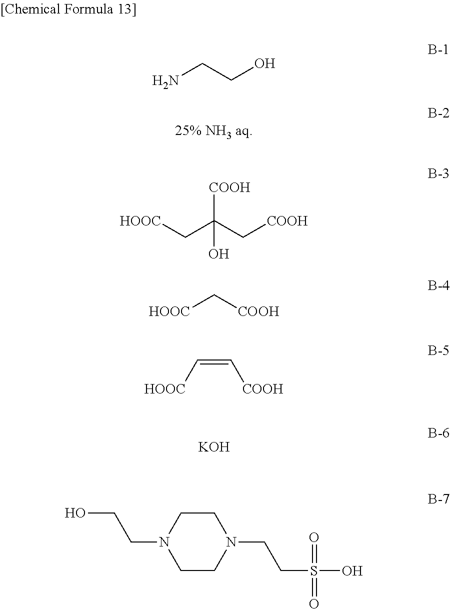

### (C) Solvent

C-1: water
C-2: diethylene glycol mono-n-butyl ether
C-3: diethylene glycol monomethyl ether
C-4: 2-methoxy-1-propanol
C-5: ethylene glycol mono-n-butyl ether
C-6: sulfolane
C-7: gamma-butyrolactone

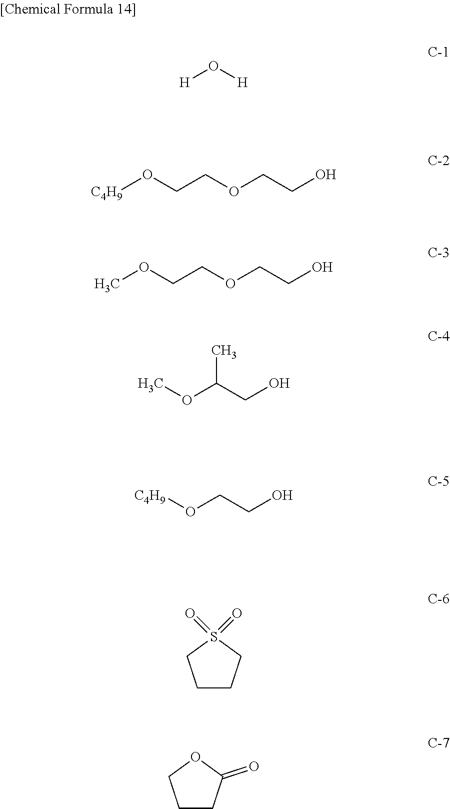

### (D) Cleaning Component

Mol-1; hydrofluoric acid
Mol-2; ammonium fluoride
Mol-3; tetramethylammonium fluoride
Mol-4; hexafluorosilicic acid
Mol-5; hydrogen peroxide

### 1. Preparation of Surface Modification Composition (1)

### Example 1

To 0.05 g of compound (A-1), 99.95 g of solvent (C-1) was added and stirred, followed by filtration through a high-density polyethylene filter having pores of 0.45 μm to prepare composition (SM-1) having a solid content concentration of 0.050%.

### Examples 2 to 26 and Comparative Examples 1 to 4

Composition (SM-2) to composition (SM-26) and composition (SR-1) to composition (SR-4) were respectively prepared by performing the same operations as in Example 1 above, except that the components were used with the types and blending amounts shown in Table 1 and Table 2. The blending amount of compound (B-2) represents the blending amount of ammonia aqueous solution.

TABLE 1

| | | Low molecular weight compound | | | | | | | | | | |
|---|---|---|---|---|---|---|---|---|---|---|---|---|
| | | Compound (A) | | Others | | (B) pH adjuster | | (C) Solvent | | | | Solid content |
| | | | Parts | | Parts | | Parts | | Parts | | Parts | concentration |
| | Composition | Type | by mass | Type | by mass | Type | by mass | Type | by mass | Type | by mass | [mass %] |
| Example 1 | SM-1 | A-1 | 0.05 | | | | | C-1 | 99.95 | | | 0.050 |
| Example 2 | SM-2 | A-2 | 0.04 | | | B-3 | 0.01 | C-1 | 99.95 | | | 0.050 |
| Example 3 | SM-3 | A-1 | 0.04 | | | B-2 | 0.01 | C-1 | 79.95 | C-2 | 20 | 0.050 |
| Example 4 | SM-4 | A-2 | 0.04 | | | B-1 | 0.01 | C-1 | 79.95 | C-3 | 20 | 0.050 |
| Example 5 | SM-5 | A-3 | 0.04 | | | B-2 | 0.01 | C-1 | 79.95 | C-4 | 20 | 0.050 |
| Example 6 | SM-6 | A-4 | 0.04 | | | B-3 | 0.01 | C-1 | 79.95 | C-5 | 20 | 0.050 |
| Example 7 | SM-7 | A-5 | 0.04 | | | B-4 | 0.01 | C-1 | 59.95 | C-2 | 40 | 0.050 |
| Example 8 | SM-8 | A-6 | 0.04 | | | B-5 | 0.01 | C-1 | 79.95 | C-2 | 20 | 0.050 |
| Example 9 | SM-9 | A-7 | 0.04 | | | B-1 | 0.01 | C-1 | 79.95 | C-2 | 20 | 0.050 |
| Example 10 | SM-10 | A-8 | 0.04 | | | B-2 | 0.01 | C-1 | 79.95 | C-2 | 20 | 0.050 |
| Example 11 | SM-11 | A-9 | 0.04 | | | B-2 | 0.01 | C-1 | 79.95 | C-2 | 20 | 0.050 |
| Example 12 | SM-12 | A-2 | 0.04 | | | B-1 | 0.01 | C-1 | 59.95 | C-2 | 40 | 0.050 |
| Example 13 | SM-13 | A-2 | 0.04 | | | B-1 | 0.01 | C-1 | 39.95 | C-2 | 60 | 0.050 |
| Example 14 | SM-14 | A-2 | 0.045 | | | B-6 | 0.005 | C-1 | 79.95 | C-6 | 20 | 0.050 |
| Example 15 | SM-15 | A-2 | 0.04 | | | B-7 | 0.01 | C-1 | 79.95 | C-7 | 20 | 0.050 |
| Example 16 | SM-16 | A-10 | 0.05 | | | | | C-1 | 79.95 | C-3 | 20 | 0.050 |
| Comparative | SR-1 | A-10 | 0.05 | | | | | C-2 | 79.95 | C-3 | 20 | 0.050 |
| Example 1 | | | | | | | | | | | | |
| Comparative | SR-2 | | | A-11 | 0.04 | B-1 | 0.01 | C-1 | 79.95 | C-2 | 20 | 0.050 |
| Example 2 | | | | | | | | | | | | |
| Comparative | SR-3 | | | A-12 | 0.04 | B-1 | 0.01 | C-1 | 79.95 | C-2 | 20 | 0.050 |
| Example 3 | | | | | | | | | | | | |
| Comparative | SR-4 | | | A-21 | 0.05 | | | C-1 | 79.95 | C-2 | 20 | 0.050 |
| Example 4 | | | | | | | | | | | | |

TABLE 2

| | Low molecular weight compound | | | | | | | | | | |
|---|---|---|---|---|---|---|---|---|---|---|---|
| | (A) Compound | | Others | | (B) pH adjuster | | (C) Solvent | | | | Solid content |
| | | Parts | | Parts | | Parts | | Parts | | Parts | concentration |
| Composition | Type | by mass | Type | by mass | Type | by mass | Type | by mass | Type | by mass | [mass %] |

| | | | | | | | | | | |
|---|---|---|---|---|---|---|---|---|---|---|
| Example 17 | SM-17 | A-13 | 0.04 | B-1 | 0.01 | C-1 | 79.95 | C-2 | 20 | 0.050 |
| Example 18 | SM-18 | A-13 | 0.04 | B-3 | 0.01 | C-1 | 79.95 | C-2 | 20 | 0.050 |
| Example 19 | SM-19 | A-14 | 0.04 | B-1 | 0.01 | C-1 | 79.95 | C-2 | 20 | 0.050 |
| Example 20 | SM-20 | A-14 | 0.04 | B-3 | 0.01 | C-1 | 79.95 | C-2 | 20 | 0.050 |
| Example 21 | SM-21 | A-15 | 0.04 | B-1 | 0.01 | C-1 | 79.95 | C-2 | 20 | 0.050 |
| Example 22 | SM-22 | A-15 | 0.04 | B-3 | 0.01 | C-1 | 79.95 | C-2 | 20 | 0.050 |
| Example 23 | SM-23 | A-16 | 0.04 | B-1 | 0.01 | C-1 | 79.95 | C-2 | 20 | 0.050 |
| Example 24 | SM-24 | A-16 | 0.04 | B-3 | 0.01 | C-1 | 79.95 | C-2 | 20 | 0.050 |
| Example 25 | SM-25 | A-17 | 0.04 | B-1 | 0.01 | C-1 | 79.95 | C-2 | 20 | 0.050 |
| Example 26 | SM-26 | A-17 | 0.04 | B-3 | 0.01 | C-1 | 79.95 | C-2 | 20 | 0.050 |

### 2. Evaluation (1)

Using composition (SM-1) to composition (SM-26) and composition (SR-1) to composition (SR-4) prepared in 1. above, the evaluations shown below were performed. The results are shown in Table 3 and Table 4.

### <Evaluation of Solubility>

The solubility of each composition obtained in 1. above was visually observed, and in the case of having transparency, it was rated as “good (∘)”, and in the case of confirming at least one of cloudiness and undissolved residue, it was rated as “poor (x)”.

### <Evaluation of Coatability>

Using the substrates shown below, the coatability of each composition was evaluated.

W: 8-inch tungsten substrate, Cu: 8-inch copper substrate, Co: 8-inch cobalt substrate, Ru: 8-inch ruthenium substrate, Al₂O₃: 8-inch alumina substrate, SiN: 8-inch silicon nitride substrate, low-k; low dielectric silicon oxide substrate

These substrates were obtained from Advantec Co., Ltd.

The various substrates shown above were cut to 3 cm×3 cm, and each composition prepared in 1. above was spin-coated using a spin coater (“MS-B300” from Mikasa Co., Ltd.) under conditions of 1,500 rpm for 20 seconds (coating step). Next, the substrate after this coating was baked at 150° C. for 180 seconds. Thereafter, the substrate was cleaned using propylene glycol monomethyl ether acetate as a rinse solution (first removal step, hereinafter also referred to as “cleaning step”). In the cleaning step, in the case of components in the composition not being adsorbed to the substrate surface, the composition is removed by the rinse solution, so no film is formed on the substrate. The coated surface of this substrate was observed with an optical microscope to confirm the presence or absence of voids and film breakage on the film surface. Substrates without voids and film breakage were rated as “good (∘)”, substrates without film breakage but with voids were rated as “acceptable (Δ)”, and substrates with both voids and film breakage were rated as “poor (x)”.

### <Evaluation of Contact Angle>

The various substrates used for coatability evaluation were cut to 3 cm×3 cm, and each composition prepared in 1. above was spin-coated using a spin coater (“MS-B300” from Mikasa Co., Ltd.) under conditions of 1,500 rpm for 20 seconds. Thereafter, the substrate was cleaned using isopropyl alcohol. For the substrate after cleaning, the static contact angle of the coated surface was measured using a contact angle meter (“Drop master DM-501” from Kyowa Interface Science Co., Ltd.). It can be said that a film is selectively formed on substrates where the static contact angle has increased significantly compared to the static contact angle of the substrate before surface treatment with the surface modification composition (Reference Example 1).

### <Evaluation of Storage Stability>

10 g of each surface modification composition prepared in 1. above was placed in a vial and stored at 50° C. for 2 weeks. The change amount in viscosity before and after the storage stability test was expressed as Ail, and cases where the change amount Δη was less than 1 Pa·s were rated as “good (∘)”, cases where the change amount Δη was 1 Pa·s or more and less than 3 Pa·s were rated as “acceptable (Δ)”, and cases where the change amount Δη was 3 Pa·s or more were rated as “poor (x)”.

### <Evaluation of Metal Corrosion Resistance (Evaluation by Etching Rate)>

Wafer pieces with a ruthenium film having a film thickness of 100 nm and wafer pieces with a molybdenum film having a film thickness of 200 nm were each cut to 30 mm×10 mm to prepare wafer pieces for etching rate evaluation (hereinafter also referred to as “evaluation wafer pieces”). Each composition prepared in 1. above was heated to 60° C., and the evaluation wafer pieces were immersed in each composition for 5 minutes. Thereafter, the evaluation wafer pieces were taken out and washed with running water, and the thicknesses of the ruthenium film and molybdenum film were measured. The thicknesses of the ruthenium film and molybdenum film were calculated by the following formulas from the resistance values (hereinafter referred to as “sheet resistance values”, unit: i/sq) obtained by measuring the resistance values by the DC four-probe method using a resistivity measuring instrument (manufactured by KLA-Tencor Corporation, model “RS-100”), and the volume resistivity of ruthenium or molybdenum.

$$Ruthenium film thickness ( nm ) = [ Volume resistivity of ruthenium film ( Ω \cdot m ) \div Sheet resistance value ( Ω / sq ) ] \times {10}^{9}$$

$$Molybdenum film thickness ( nm ) = [ Volume resistivity of molybdenum film ( Ω \cdot m ) \div Sheet resistance value ( Ω / sq ) ] \times {10}^{9}$$

The etching rate was calculated by the following formulas from the change amount in thickness of the ruthenium film or molybdenum film before and after immersion in the surface modification composition.

$$Ruthenium film etching rate ( nm / min ) = ( Ruthenium film thickness before etching ( nm ) - Ruthenium film thickness after etching ( nm ) ) / Etching time ( min )$$

$$Molybdenum film etching rate ( nm / min ) = ( Molybdenum film thickness before etching ( nm ) - Molybdenum film thickness after etching ( nm ) ) / Etching time ( min )$$

The evaluation criteria for the etching rate of the ruthenium film are as follows. It can be said that the smaller the etching rate of the ruthenium film, the better the metal corrosion resistance of the surface modification composition.

### (Evaluation Criteria)

A: In the case of an etching rate of less than 1.5 nm/min, it was judged to be very good.

B: In the case of an etching rate of 1.5 nm/min or more and less than 3 nm/min, it was judged to be good because it could be put to practical use.

C: In the case of an etching rate of 3 nm/min or more, it was judged to be poor because the etching rate was large and practical use was difficult.

The evaluation criteria for the etching rate of the molybdenum film are as follows. It can be said that the smaller the etching rate of the molybdenum film, the better the metal corrosion resistance of the surface modification composition.

### (Evaluation Criteria)

A: In the case of an etching rate of less than 20 nm/min, it was judged to be very good.

B: In the case of an etching rate of 20 nm/min or more, it was judged to be poor because the etching rate was large and practical use was difficult.

### <Evaluation of Dry Etch Residue Removal Performance (Evaluation by Etching Rate)>

A substrate to be processed was obtained by performing dry etching treatment on a LowK film substrate using a reactive ion etching apparatus (RIE-10NR). The obtained substrate to be processed was cut to 3.5 cm×3.5 cm, and immersed in each composition prepared in 1. above for 1 minute respectively. Thereafter, the wafer pieces (substrates to be processed) were taken out and cleaned with water and isopropyl alcohol. The F component on the surface of the substrate to be processed after cleaning was quantified by X-ray photoelectron spectroscopy (manufactured by ULVAC, model “Quantum2000”), and the ratio of the quantified value of the F component on the surface-treated substrate was calculated as cleaning efficiency (%) using the quantified value of the F component on the substrate not immersed in each composition as a reference value.

### (Evaluation Criteria)

A: Cleaning efficiency of 98% or more (good)
B: Cleaning efficiency of less than 98% and 90% or more (acceptable)
C: Cleaning efficiency of less than 90% (poor)

### (Dry Etching Conditions)

Gas flow rate: Ar/C₄F₈/N₂=100/50/33 sccm
Plasma power: 170 W/40 MHz (high frequency), 80 W/13 MHz (low frequency)
Pressure: 50 mTorr
Processing time: 100 seconds

### <Evaluation of Metal Oxide Blocking Performance (Evaluation of ALD Resistance)>

For the substrates surface-coated with tungsten substrates (W substrates) using each surface modification composition prepared in 1. above (referred to as “surface-treated substrates”), metal oxide blocking evaluation was performed to evaluate the degree of suppression of oxide layer formation by ALD. As a control, W substrates not subjected to surface treatment with each surface modification composition (referred to as “untreated substrates”) were used, and ALD was performed in the same manner as the surface-treated substrates. ALD was performed using Cambridge Nanotech FIJI at Stanford University under the conditions shown below. Trimethylaluminum was used as the precursor, and water was used as the co-catalyst. The ALD cycle was fixed at 47 cycles.

### (ALD Conditions)

Film type: ALD Al₂O₃
Chamber: Cambridge Nanotech Fiji
Stage temperature: 200° C.
Processing time: 0.3 seconds trimethylaluminum/15 seconds purge/0.06 seconds water/23 seconds purge
Thickness on W substrate: 5.4 nm (ellipsometry)
Loading: Cool stage for 5 minutes before loading
Queue time: Within 3 hours after removal

The Al component on the substrate surface of W substrates after ALD (surface-treated substrates and untreated substrates) was quantified by X-ray photoelectron spectroscopy (ESCA). ESCA was performed using “Quantum2000” from ULVAC, and the Al component excluding film components and substrate components was quantified at Al2p (72-78 eV) under conditions of 100 μmφ. Subsequently, the quantified value of the Al component with the untreated substrate as the measurement target was used as a reference value, and the blocking rate (%) was calculated as the extent to which the quantified value of the Al component of the surface-treated substrate decreased from the reference value. The larger the blocking rate value, the more the film formed on the W substrate by the surface modification composition is formed by high-density adsorption of components in the surface modification composition (low molecular weight compound in Table 1) onto the W substrate surface, and it can be said to have high blocking performance against metal oxide formation by ALD. Cases where the blocking rate was 98% or more were rated as “good (∘)”, cases of less than 98% but 90% or more were rated as “acceptable (Δ)”, and cases of less than 90% were rated as “poor (x)”.

### <Measurement of Metal Content>

Each composition was diluted 20-fold with diethylene glycol butyl ether/ultrapure water=80/20 (parts by mass), and the metal content of sodium, potassium, and calcium was measured using a NexION 5000 ICP mass spectrometer (manufactured by Perkin Elmer). The evaluation was rated as “good (∘)” in the case of a total amount of sodium, potassium, and calcium of less than 100 ppb, “acceptable (Δ)” in the case of 100 ppb or more and 10 ppm or less, and “unacceptable (x)” in the case of more than 10 ppm.

TABLE 3

| | | | | | | | | | | | | Metal | | | | |
|---|---|---|---|---|---|---|---|---|---|---|---|---|---|---|---|---|
| | | | | Surface contact angle | | | | | | | | corrosion | | Residue | | |
| | Com- | Sol- | Coat- | value/degree | | | | | | | Storage | resistance | | removal | ALD | Metal |
| | position | ubility | ability | W | Cu | Co | Ru | Al2O3 | SiN | low-k | stability | Ru | Mo | performance | resistance | content |
| Reference | blank | — | — | 42 | 63 | 56 | 73 | 32 | 26 | 85 | — | — | — | — | — | — |
| Example 1 | | | | | | | | | | | | | | | | |
| Example 1 | SM-1 | ∘ | ∘ | 91 | 96 | 93 | 93 | 33 | 28 | 86 | Δ | A | A | B | ∘ | ∘ |
| Example 2 | SM-2 | ∘ | ∘ | 90 | 95 | 92 | 92 | 34 | 30 | 86 | ∘ | A | A | B | ∘ | ∘ |
| Example 3 | SM-3 | ∘ | ∘ | 91 | 95 | 92 | 92 | 33 | 27 | 86 | ∘ | A | A | B | ∘ | ∘ |
| Example 4 | SM-4 | ∘ | ∘ | 91 | 94 | 93 | 93 | 32 | 28 | 86 | ∘ | A | A | B | ∘ | ∘ |
| Example 5 | SM-5 | ∘ | ∘ | 90 | 95 | 92 | 92 | 34 | 28 | 86 | ∘ | A | A | B | ∘ | ∘ |
| Example 6 | SM-6 | ∘ | ∘ | 91 | 95 | 92 | 92 | 35 | 29 | 86 | ∘ | A | A | B | ∘ | ∘ |
| Example 7 | SM-7 | ∘ | ∘ | 91 | 94 | 91 | 93 | 35 | 29 | 86 | ∘ | A | A | B | Δ | Δ |
| Example 8 | SM-8 | ∘ | ∘ | 91 | 95 | 93 | 86 | 33 | 28 | 86 | ∘ | A | A | B | ∘ | ∘ |
| Example 9 | SM-9 | ∘ | ∘ | 91 | 95 | 92 | 92 | 32 | 29 | 86 | ∘ | A | A | B | ∘ | ∘ |
| Example 10 | SM-10 | ∘ | ∘ | 90 | 95 | 93 | 93 | 33 | 27 | 86 | ∘ | A | A | B | ∘ | ∘ |
| Example 11 | SM-11 | ∘ | ∘ | 91 | 95 | 93 | 93 | 34 | 29 | 86 | ∘ | A | A | B | ∘ | ∘ |
| Example 12 | SM-12 | ∘ | ∘ | 90 | 92 | 90 | 91 | 32 | 28 | 86 | ∘ | A | A | B | ∘ | ∘ |
| Example 13 | SM-13 | ∘ | ∘ | 90 | 95 | 92 | 92 | 33 | 28 | 86 | ∘ | A | A | B | ∘ | ∘ |
| Example 14 | SM-14 | ∘ | Δ | 82 | 85 | 84 | 83 | 34 | 27 | 86 | ∘ | A | A | B | Δ | Δ |
| Example 15 | SM-15 | ∘ | Δ | 81 | 86 | 82 | 84 | 33 | 29 | 86 | ∘ | A | A | B | Δ | Δ |
| Example 16 | SM-16 | ∘ | Δ | 81 | 85 | 83 | 83 | 33 | 28 | 86 | ∘ | A | A | B | Δ | ∘ |
| Comparative | SR-1 | ∘ | Δ | 81 | 85 | 81 | 83 | 33 | 30 | 84 | ∘ | B | B | B | x | ∘ |
| Example 1 | | | | | | | | | | | | | | | | |
| Comparative | SR-2 | x | x | 46 | 65 | 55 | 72 | 34 | 28 | 84 | x | C | B | C | x | Δ |
| Example 2 | | | | | | | | | | | | | | | | |
| Comparative | SR-3 | ∘ | ∘ | 62 | 64 | 65 | 62 | 32 | 28 | 85 | ∘ | A | A | B | x | ∘ |
| Example 3 | | | | | | | | | | | | | | | | |
| Comparative | SR-4 | ∘ | ∘ | 44 | 64 | 57 | 63 | 31 | 27 | 85 | ∘ | C | B | B | x | x |
| Example 4 | | | | | | | | | | | | | | | | |

TABLE 4

| | | | | | | | | | | | | Metal | | | | |
|---|---|---|---|---|---|---|---|---|---|---|---|---|---|---|---|---|
| | | | | Surface contact angle | | | | | | | | corrosion | | Residue | | |
| | Com- | Sol- | Coat- | value/degree | | | | | | | Storage | resistance | | removal | ALD | Metal |
| | position | ubility | ability | W | Cu | Co | Ru | Al2O3 | SiN | low-k | stability | Ru | Mo | performance | resistance | content |
| Example 17 | SM-17 | ∘ | ∘ | 90 | 92 | 89 | 88 | 32 | 27 | 85 | ∘ | A | A | B | ∘ | ∘ |
| Example 18 | SM-18 | ∘ | ∘ | 91 | 91 | 90 | 87 | 33 | 28 | 86 | ∘ | A | A | B | ∘ | ∘ |
| Example 19 | SM-19 | ∘ | ∘ | 88 | 90 | 87 | 89 | 32 | 28 | 86 | ∘ | A | A | B | ∘ | ∘ |
| Example 20 | SM-20 | ∘ | ∘ | 90 | 91 | 87 | 90 | 32 | 27 | 85 | ∘ | A | A | B | ∘ | ∘ |
| Example 21 | SM-21 | ∘ | ∘ | 90 | 92 | 90 | 89 | 32 | 28 | 86 | ∘ | A | A | B | ∘ | ∘ |
| Example 22 | SM-22 | ∘ | ∘ | 89 | 89 | 90 | 89 | 33 | 28 | 86 | ∘ | A | A | B | ∘ | ∘ |
| Example 23 | SM-23 | ∘ | ∘ | 91 | 91 | 87 | 88 | 33 | 28 | 85 | ∘ | A | A | A | ∘ | ∘ |
| Example 24 | SM-24 | ∘ | ∘ | 90 | 89 | 90 | 89 | 32 | 27 | 86 | ∘ | A | A | A | ∘ | ∘ |
| Example 25 | SM-25 | ∘ | ∘ | 93 | 92 | 90 | 88 | 32 | 28 | 85 | ∘ | A | A | B | ∘ | ∘ |
| Example 26 | SM-26 | ∘ | ∘ | 92 | 91 | 89 | 89 | 33 | 27 | 86 | ∘ | A | A | B | ∘ | ∘ |

As can be seen from the above results, the surface modification compositions of Examples 1 to 26 using compound (A) as the film forming material and including water had good solubility of compound (A) in water, and also had good coatability and storage stability. Moreover, by using the surface modification compositions of Examples 1 to 26, films could be formed with high selectivity and high density on metal surfaces. Furthermore, the films formed by the surface modification compositions of Examples 1 to 26 showed good metal corrosion resistance. Additionally, in the case of using compounds (A-1) to (A-9) as the film forming material, the coatability and ALD resistance were better than in the case of using compound (A-10). From this, it can be said that in the case of the monovalent organic group R¹ in compound (A) being bonded to a nitrogen atom constituting the nitrogen-containing heterocyclic ring or being bonded to a nitrogen atom bonded to the nitrogen-containing heterocyclic ring, the coatability of the composition could be improved and a higher density film could be formed. Moreover, by further blending a pH adjuster, surface modification compositions with further improved storage stability could be obtained (Examples 2 to 15, 17 to 26).

In contrast, the surface modification composition of Comparative Example 1 using only an organic solvent as the solvent showed inferior results in coatability and ALD resistance compared to Example 16 including water. Moreover, the surface modification composition of Comparative Example 2 using compound (A-11) instead of compound (A) had low solubility in water and was evaluated as having poor storage stability. Additionally, the selective modification of metal surfaces, metal corrosion resistance, and metal oxide blocking performance were also insufficient. The surface modification composition of Comparative Example 3 using compound (A-12) was inferior to Examples 1 to 26 in selective modification of metal surfaces and metal oxide blocking performance, and the surface modification composition of Comparative Example 4 using compound (A-21) was inferior to Examples 1 to 26 in selective modification of metal surfaces, metal corrosion resistance, and metal oxide blocking performance.

### 3. Preparation of Surface Modification Composition (2)

### Example 27

To 0.03 g of compound (A-16), 99.95 g of solvent (C-1) was added and stirred, then 0.01 g of compound (Mol-1) and 0.01 g of compound (B-1) were added, and after stirring, the mixture was filtered through a high-density polyethylene filter having pores of 0.45 μm to prepare composition (SM-27) having a solid content concentration of 0.05%.

### Examples 28 to 38

Composition (SM-28) to composition (SM-38) were respectively prepared by performing the same operations as in Example 27 above, except that the components were used with the types and blending amounts shown in Table 5.

TABLE 5

| | | Low molecular | | | | | | | | | | |
|---|---|---|---|---|---|---|---|---|---|---|---|---|
| | | weight compound | | (B) pH | | (D) Cleaning | | | | | | |
| | | (A) Compound | | adjuster | | component | | (C) Solvent | | | | Solid content |
| | | | Parts | | Parts | | Parts | | Parts | | Parts | concentration |
| | Composition | Type | by mass | Type | by mass | Type | by mass | Type | by mass | Type | by mass | [mass %] |
| Example 27 | SM-27 | A-16 | 0.03 | B-1 | 0.01 | Mol-1 | 0.01 | C-1 | 99.95 | | | 0.05 |
| Example 28 | SM-28 | A-16 | 0.03 | B-3 | 0.01 | Mol-2 | 0.01 | C-1 | 79.95 | C-4 | 20 | 0.05 |
| Example 29 | SM-29 | A-18 | 0.03 | B-1 | 0.01 | Mol-2 | 0.01 | C-1 | 79.95 | C-4 | 20 | 0.05 |
| Example 30 | SM-30 | A-18 | 0.03 | B-3 | 0.01 | Mol-3 | 0.01 | C-1 | 79.95 | C-5 | 20 | 0.05 |
| Example 31 | SM-31 | A-19 | 0.03 | B-1 | 0.01 | Mol-2 | 0.01 | C-1 | 79.95 | C-4 | 20 | 0.05 |
| Example 32 | SM-32 | A-19 | 0.03 | B-3 | 0.01 | Mol-3 | 0.01 | C-1 | 79.95 | C-4 | 20 | 0.05 |
| Example 33 | SM-33 | A-19 | 0.03 | B-1 | 0.01 | Mol-4 | 0.01 | C-1 | 79.95 | C-4 | 20 | 0.05 |
| Example 34 | SM-34 | A-19 | 0.03 | B-3 | 0.01 | Mol-5 | 0.01 | C-1 | 79.95 | C-5 | 20 | 0.05 |
| Example 35 | SM-35 | A-20 | 0.03 | B-1 | 0.01 | Mol-1 | 0.01 | C-1 | 79.95 | C-4 | 20 | 0.05 |
| Example 36 | SM-36 | A-20 | 0.03 | B-3 | 0.01 | Mol-2 | 0.01 | C-1 | 79.95 | C-4 | 20 | 0.05 |
| Example 37 | SM-37 | A-20 | 0.03 | B-1 | 0.01 | Mol-3 | 0.01 | C-1 | 79.95 | C-5 | 20 | 0.05 |
| Example 38 | SM-38 | A-20 | 0.03 | B-3 | 0.01 | Mol-5 | 0.01 | C-1 | 79.95 | C-4 | 20 | 0.05 |

### 2. Evaluation (2)

Using composition (SM-27) to composition (SM-38) prepared in 3. above, the same evaluations as in Examples 1 to 26 and Comparative Examples 1 to 4 were performed. The results are shown in Table 6.

TABLE 6

| | | | | | | | | | | | | Metal | | | | |
|---|---|---|---|---|---|---|---|---|---|---|---|---|---|---|---|---|
| | | | | Surface contact angle | | | | | | | | corrosion | | Residue | | |
| | Com- | Sol- | Coat- | value/degree | | | | | | | Storage | resistance | | removal | ALD | Metal |
| | position | ubility | ability | W | Cu | Co | Ru | Al2O3 | SiN | low-k | stability | Ru | Mo | performance | resistance | content |
| Example 27 | SM-27 | ∘ | ∘ | 93 | 92 | 91 | 89 | 32 | 27 | 85 | ∘ | A | A | A | ∘ | ∘ |
| Example 28 | SM-28 | ∘ | ∘ | 92 | 91 | 90 | 89 | 33 | 28 | 86 | ∘ | A | A | A | ∘ | ∘ |
| Example 29 | SM-29 | ∘ | ∘ | 91 | 93 | 88 | 89 | 32 | 28 | 86 | ∘ | A | A | B | ∘ | ∘ |
| Example 30 | SM-30 | ∘ | ∘ | 93 | 92 | 89 | 90 | 32 | 27 | 85 | ∘ | A | A | B | ∘ | ∘ |
| Example 31 | SM-31 | ∘ | ∘ | 92 | 92 | 90 | 89 | 32 | 28 | 86 | ∘ | A | A | A | ∘ | ∘ |
| Example 32 | SM-32 | ∘ | ∘ | 92 | 91 | 90 | 89 | 33 | 28 | 86 | ∘ | A | A | A | ∘ | ∘ |
| Example 33 | SM-33 | ∘ | ∘ | 93 | 91 | 89 | 90 | 33 | 28 | 85 | ∘ | A | A | A | ∘ | ∘ |
| Example 34 | SM-34 | ∘ | ∘ | 93 | 90 | 91 | 89 | 32 | 27 | 86 | ∘ | A | A | A | ∘ | ∘ |
| Example 35 | SM-35 | ∘ | ∘ | 92 | 92 | 91 | 91 | 32 | 28 | 85 | ∘ | A | A | B | ∘ | ∘ |
| Example 36 | SM-36 | ∘ | ∘ | 91 | 94 | 90 | 89 | 33 | 27 | 87 | ∘ | A | A | B | ∘ | ∘ |
| Example 37 | SM-37 | ∘ | ∘ | 92 | 92 | 91 | 88 | 33 | 27 | 88 | ∘ | A | A | B | ∘ | ∘ |
| Example 38 | SM-38 | ∘ | ∘ | 93 | 91 | 90 | 89 | 33 | 27 | 86 | ∘ | A | A | B | ∘ | ∘ |

As shown in Table 6, the surface modification compositions of Examples 27 to 38 using compound (A) as the film forming material and including water also had good solubility of compound (A) in water, and also had good coatability and storage stability. Moreover, by using the surface modification compositions of Examples 27 to 38, films could be formed with high selectivity and high density on metal surfaces. Furthermore, the films formed by the surface modification compositions of Examples 27 to 38 showed good metal corrosion resistance and good residue removal performance.

1. A method for selectively modifying a substrate surface, comprising:
coating a composition on a surface of a substrate,
wherein the composition comprises a compound (A), which has a nitrogen-containing heterocyclic ring and a monovalent organic group having 4 or more carbon atoms, and water.

2. The method for selectively modifying the substrate surface according to claim 1, wherein the substrate comprises a first region and a second region having a different material from the first region, and
a film is formed on the first region by coating the composition on the surface of the substrate comprising the first region and the second region.

3. The method for selectively modifying the substrate surface according to claim 2, wherein the first region is formed of a conductive material, and
the second region is formed of an insulating material.

4. The method for selectively modifying the substrate surface according to claim 2, further comprising:
removing components derived from the composition on the second region by bringing the surface of the substrate into contact with a rinse solution after coating the composition.

5. The method for selectively modifying the substrate surface according to claim 4, further comprising:
bringing alcohol, dilute acid, hydrogen peroxide water, ozone, plasma, ammonia, or ammonium fluoride salt aqueous solution into contact with the substrate surface after contact with the rinse solution.

6. The method for selectively modifying the substrate surface according to claim 4, further comprising:
forming a metal layer on the second region after contact with the rinse solution.

7. The method for selectively modifying the substrate surface according to claim 6, further comprising:
removing the film on the first region formed by the composition after formation of the metal layer.

8. The method for selectively modifying the substrate surface according to claim 1, wherein the monovalent organic group having 4 or more carbon atoms, which is included in the compound (A), is bonded to a nitrogen atom constituting the nitrogen-containing heterocyclic ring, or is bonded to a nitrogen atom that is bonded to the nitrogen-containing heterocyclic ring directly or via a divalent linking group.

9. The method for selectively modifying the substrate surface according to claim 1, wherein the composition further comprises a pH adjuster, and the pH adjuster is an organic acid, an organic base, or ammonia.

10. (canceled)

11. The method for selectively modifying the substrate surface according to claim 9, wherein the pH adjuster is a carboxy group-containing chain compound, a chain monoamine compound, or ammonia.

12. The method for selectively modifying the substrate surface according to claim 1, wherein the monovalent organic group having 4 or more carbon atoms, which is included in the compound (A), is a monovalent hydrocarbon group having 4 or more carbon atoms, a monovalent halogenated hydrocarbon group having 4 or more carbon atoms, —R³—O—R⁶ or —CR⁴(OH)—R⁶ (where R³ is an alkanediyl group having 1 to 3 carbon atoms, R⁴ is a hydrogen atom or a methyl group, and R⁶ is a monovalent hydrocarbon group having 4 or more carbon atoms).

13. The method for selectively modifying the substrate surface according to claim 1, wherein the monovalent organic group having 4 or more carbon atoms, which is included in the compound (A), is a monovalent chain hydrocarbon group having 4 or more carbon atoms, —R³—O—R⁷ or —CR⁴(OH)—R⁷ (where R³ is an alkanediyl group having 1 to 3 carbon atoms, R⁴ is a hydrogen atom or a methyl group, and R⁷ is a monovalent chain hydrocarbon group having 4 or more carbon atoms).

14. The method for selectively modifying the substrate surface according to claim 1, wherein the composition further comprises an organic solvent, and
a content of the organic solvent in the composition is 60% by mass or less relative to a total amount of the composition.

15. The method for selectively modifying the substrate surface according to claim 14, wherein the organic solvent included in the composition is at least one selected from a group consisting of alcohols, ethers, ketones, sulfones, amides, cyclic amines, lactams, and esters.

16. The method for selectively modifying the substrate surface according to claim 1, wherein a content of the water is 10% by mass or more relative to a total amount of the composition.

17. The method for selectively modifying the substrate surface according to claim 1, wherein the composition further comprises a cleaning component.

18. The method for selectively modifying the substrate surface according to claim 17, wherein the cleaning component is a fluorine compound.

19. A method for producing a surface-treated substrate, comprising:
coating a composition on a surface of a substrate to selectively modify the surface of the substrate,
wherein the composition comprises a compound (A), which has a nitrogen-containing heterocyclic ring and a monovalent organic group having 4 or more carbon atoms, and water.

20. A composition, used for selectively modifying a substrate surface, the composition comprising:
a compound (A), which has a nitrogen-containing heterocyclic ring and a monovalent organic group having 4 or more carbon atoms; and
water,
wherein the monovalent organic group having 4 or more carbon atoms, which is included in the compound (A), is bonded to a nitrogen atom constituting the nitrogen-containing heterocyclic ring, or is bonded to a nitrogen atom that is bonded to the nitrogen-containing heterocyclic ring directly or via a divalent linking group.

21. (canceled)

22. (canceled)

23. (canceled)

24. The composition according to claim 20, further comprising an organic solvent,
wherein a content of the organic solvent is 60% by mass or less relative to a total amount of the composition.
